(19) United States
(12) Patent Application Publication
(10) Pub. No.: US 2026/0223671 A1
(43) Pub. Date: Jul. 30, 2026

(54) METHODS AND APPARATUS TO PROTECT INTEGRATED CIRCUIT PACKAGES AND THEIR INTERCONNECTS FROM SHOCK LOADS

(71) Applicant: Intel Corporation, Santa Clara, CA (US)

(72) Inventors: Guebum Han, Portland, OR (US); Eric W. Buddrius, Hillsboro, OR (US); Emery Evon Frey, Portland, OR (US); Jeffory L. Smalley, East Olympia, WA (US); Ralph V. Miele, Hillsboro, OR (US)

(73) Assignee: Intel Corporation, Santa Clara, CA (US)

(21) Appl. No.: 19/573,834

(22) Filed: Mar. 20, 2026

(51) Int. Cl. H10W 40/20

(52) U.S. Cl. CPC H10W 40/233

(57) ABSTRACT

Systems, apparatus, articles of manufacture, and methods to protect integrated circuit packages and their interconnects from shock loads are disclosed. An example apparatus includes a heatsink, and a spring-loaded fastener to urge the heatsink against an integrated circuit package. The integrated circuit package is coupled to a circuit board. The integrated circuit package is between the heatsink and the circuit board. The example apparatus includes a lock to restrain movement of the heatsink relative to the circuit board independent of the spring-loaded fastener.

### BACKGROUND

The demand for greater computing power and faster computing times continues to grow. This has led to higher-density connectors on computer hardware components to transfer signals more quickly. Some integrated circuit (IC) chips (e.g., land grid array (LGA) chips, pin grid array (PGA) chips, etc.) are communicatively coupled to printed circuit boards (PCBs) via sockets. Such sockets are constructed to receive and electrically couple to contacts on IC packages containing the chips. Other types of chips (e.g., ball grid array (BGA) chips) are communicatively coupled directly to PCBs via solder joints. Regardless of the means of connection between an IC package and an underlying PCB, a thermal cooling assembly (e.g., a heatsink assembly) is often mechanically and thermally coupled to the IC package on a side opposite to a circuit board to which the package is connected. In some instances, the heatsink provides a compressive load on the IC package to ensure reliable thermal coupling between the package and the heatsink.

### BRIEF DESCRIPTION OF THE DRAWINGS

FIG. 1 is a schematic of an example heat dissipating component stack experiencing a shock load.

FIG. 2 illustrates an example component stack corresponding to a first example implementation of the component stack of FIG. 1.

FIG. 3 is an enlarged view of one of the example mechanical locks shown in FIG. 2.

FIG. 4 is a cross-sectional view of the example mechanical locks shown in FIG. 3.

FIG. 5 is an enlarged view of the example locking collar of FIGS. 2-4.

FIG. 6 illustrates an example component stack corresponding to a second example implementation of the component stack of FIG. 1.

FIG. 7 is an exploded view of one of the example mechanical locks shown in FIG. 6.

FIGS. 8-10 each show a cross-sectional top view and a cross-sectional side view of the example mechanical lock shown in FIG. 7 at different stages of assembly.

FIG. 11 illustrates a variation to the example mechanical lock shown in FIGS. 7-10.

FIG. 12 illustrates an example component stack corresponding to a third example implementation of the component stack of FIG. 1.

FIG. 13 illustrates an example component stack corresponding to a fourth example implementation of the component stack of FIG. 1.

FIG. 14 is a flowchart representative of an example method of assembling any one of the example component stacks of FIG. 1-13.

FIG. 15 is a top view of a wafer including dies that may be included in an IC package constructed in accordance with teachings disclosed herein.

FIG. 16 is a cross-sectional side view of an IC device that may be included in an IC package constructed in accordance with teachings disclosed herein.

FIG. 17 is a cross-sectional side view of an IC package that may be used to implement the example IC package of FIG. 1.

FIG. 18 is a cross-sectional side view of an IC device assembly that may include an IC package constructed in accordance with teachings disclosed herein.

FIG. 19 is a block diagram of an example electrical device that may include an IC package constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

As integrated circuits, such as processor chips, continue to increase in size and power density, thermal management solutions (e.g., heatsink assemblies) have also continued to increase in size. Known heatsink assemblies are typically mounted to the backside of an integrated circuit (IC) package as part of an IC package heat dissipating component stack (or simply “component stack” for short). Such component stacks often include a bolster plate that surrounds the IC package on a first side of a printed circuit board (PCB) with a backplate on the other side of the PCB, opposite the IC package. In some cases, a socket is positioned between the IC package and the PCB. However, in other instances, the IC package is directly connected to the PCB (e.g., via solder joints). The bolster plate is typically attached to the backplate through the PCB. Further, the bolster plate is attached to the heatsink assembly that extends over the IC package. More particularly, the heatsink assembly is often connected to the bolster plate via spring-loaded fasteners that urge the heatsink assembly and the bolster plate (with the backplate attached thereto) towards one another. This results in a compressive force that urges the heatsink assembly towards the IC package, which is, in turn, urged towards the PCB. In cases where the IC package is inserted into a socket on the PCB, this compressive force is important to ensure reliable electrical connection between the IC package and the socket. Further, regardless of whether there is a socket present, the compressive force generated by the fasteners connecting the heatsink assembly to the bolster plate ensures reliable thermal coupling between the IC package and the heatsink assembly.

A challenge with known heat dissipating component stacks is that forces from shocks to and/or vibrations of the heatsink assembly pass through the IC package. That is, the design of known component stacks fails to distribute forces across multiple paths, thereby concentrating stress at vulnerable connection points (e.g., ball grid array (BGA) solder joints when the IC package is a surface-mounted BGA package). When these concentrated forces exceed the mechanical limits of the BGA interconnects, they can cause solder joint fractures, resulting in loss of electrical connectivity between the IC package and the underlying PCB. This problem is becoming an increasing concern as heatsink assemblies continue to increase in size to accommodate larger IC packages. Larger heatsink assemblies is a concern because an increase in size generally corresponds to an increase in mass, and an increase in mass corresponds to an increase in the magnitude of shock-induced forces.

A second challenge with known component stacks that is becoming a greater concern as heatsink assemblies get larger and heavier stems from the fact that known component stacks rely on the spring-loaded fasteners to both (1) retain heatsink assemblies during shock events and (2) provide adequate compression for reliable thermal coupling (e.g., sufficient compression of a thermal interface material (TIM) between the heatsink assembly and the IC package) and mechanical stability during normal operation. The dual objectives create conflicting design constraints. Specifically, the goal of retaining a heatsink assembly during a shock event depends on relatively stiff fasteners (especially for high-mass thermal solutions that are becoming more common as packages increase in size). On the other hand, achieving the goal of providing the proper (e.g., optimal) Load on an IC package depends on the fasteners having a relatively low stiffness so that the compression forces can be gradually introduced in a manner that can accommodate for tolerance variation. In short, a suitable (e.g., optimal) load on an IC package for purposes of reliable thermal coupling under normal operations may be insufficient to adequately secure a high-mass thermal solution under shock conditions.

Examples disclosed herein mitigate the above challenges by including locking mechanisms that operate independent of known spring-loaded fasteners traditionally used to press a heatsink assembly against an IC package. The example locking mechanisms disclosed herein serve to lock or secure the heatsink assembly in place relative to the IC package (and other parts of a component stack) to provide a load path for forces generated during a shock event that bypass the IC package. In some examples, this load path is in addition to the traditional spring-loaded fasteners, which are still present. Providing an additional load path diverts forces (e.g., shock-induced forces) away from the IC package so as to reduce (e.g., minimize) stress on the BGA solder joints, while simultaneously increasing system stiffness to retain the heatsink assembly in place. In some disclosed examples, the traditional fasteners discussed above are eliminated. In other examples, the traditional fasteners remain and apply compressive forces on the component stack to achieve suitable (e.g., optimal) loading of the IC package during normal operation. Example locking mechanisms can be relatively stiff to meet the high loads associated with high-mass shock events. Further, inasmuch as the known fasteners no longer need to be (e.g., solely) relied on to handle shock events, the fasteners can be tailored with less stiffness for better control of the compressive loads applied to the IC package. That is, by separating stiffness reinforcement from package compression loading, known fasteners can be adapted (e.g., optimized) specifically for proper package compression through the use of relatively soft compliance characteristics to reduce (e.g., minimize) tolerance sensitivity.

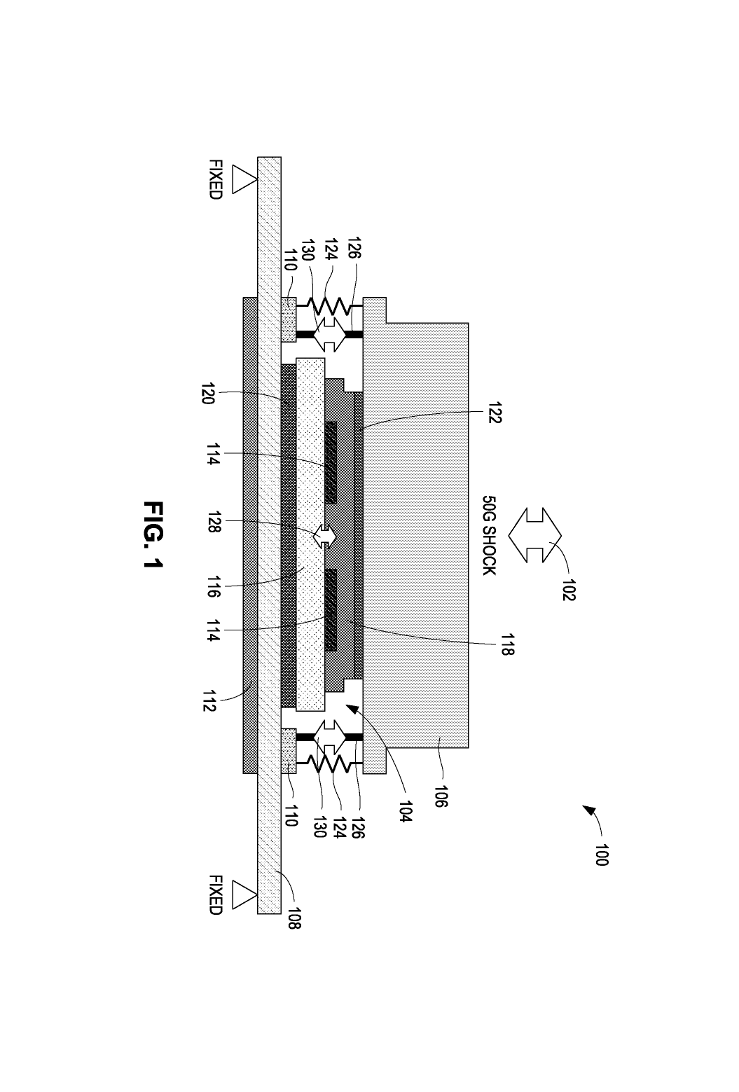

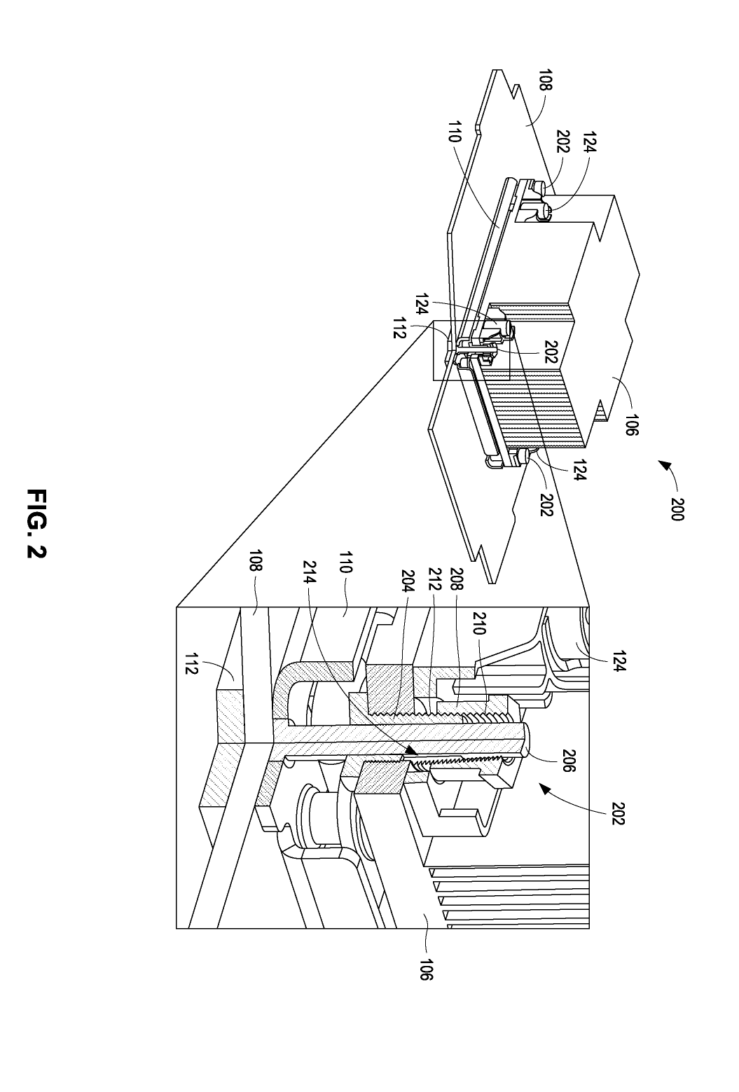

FIG. 1 is a schematic of an example heat dissipating component stack 100 experiencing a shock load 102. FIG. 1 is a generic schematic intended to illustrate the working principles of examples disclosed herein. Specific example implementations of the component stack 100 are provided further below in connection with FIGS. 2-13. In the illustrated example, the component stack 100 includes an integrated circuit (IC) package 104 stacked between a heatsink 106 (e.g., means for cooling the IC package 104) and a printed circuit board (PCB) 108 (e.g., a motherboard). Further, the example component stack 100 includes a bolster plate 110 adjacent to and surrounding the IC package 104 on the PCB 108, and a backplate 112 on the opposite side of the PCB 108 to the IC package 104 and the bolster plate 110. In some examples, at least one of the bolster plate 110 or the backplate 112 is omitted.

As shown in the illustrated example, the IC package 104 includes one or more semiconductor dies 114 (e.g., electrical circuits on a semiconductor substrate) that are mounted on a package substrate 116. In this example, the semiconductor dies 114 are covered by a lid or integrated heat spreader (IHS) 118. In some examples, the IHS 118 is omitted. The semiconductor dies 114 can perform processing functions, memory functions, and/or any other suitable functions. The semiconductor dies 114 can include any type of circuitry, including memory, interface circuitry, communication circuitry, control circuitry, and/or processor circuitry such as programmable microprocessors, one or more FPGAs, one or more CPUs, one or more GPUs, one or more DSPs, one or more XPUs, one or more ASICs, and/or one or more microcontrollers.

In the illustrated example of FIG. 1, the IC package 104 is directly mounted (e.g., mechanically and electrically coupled) to the PCB 108 via solder joints associated with a ball grid array (BGA) 120. In other examples, the IC package 104 includes a land grid array (LGA) that is electrical coupled PCB via corresponding solder joints. In other examples, the IC package 104 (whether a BGA chip or an LGA chip) is electrically coupled to the PCB 108 via a socket on the PCB 108 that is constructed to receive the IC package 104. In this example, a thermal interface material (TIM) 122 is provided between the IC package 104 and the heatsink 106 to facilitate the transfer of heat from the IC package 104 to the heatsink 106.

In some examples, the backplate 112 is rigidly affixed to the bolster plate 110 through the PCB 108 to provide structural rigidity to the PCB 108. Further, as shown in FIG. 1, the heatsink 106 is coupled to the bolster plate 110 (and, by extension, the backplate 112) via spring-loaded fasteners 124. In some examples, the spring-loaded fasteners 124 connect directly to the backplate 112 (e.g., through holes in the bolster plate 110. The spring-loaded fasteners generate a compressive load that urges the heatsink 106 and the backplate 112 (at opposite ends of the component stack 100) toward one another. As a result, the heatsink 106 is urged towards the IC package 104, thereby placing the TIM 122 in compression. Thus, the spring-loaded fasteners 124 are examples of means for urging the heatsink 106 towards the IC package 104. Compression of the TIM 122 helps to improve heat transfer between the IC package 104 and the heatsink 106 for better thermal dissipation. However, too much compression of the TIM 122 can deleteriously affect heat transfer. Accordingly, in some examples, the spring-loaded fasteners 124 are constructed to have a relatively low stiffness so as not to compress the TIM 122 too much and to accommodate variation in tolerances between different IC packages.

While the spring-loaded fasteners 124 can be tuned to provide a suitable (e.g., optimal) amount of compression on the TIM 122 during normal operations, the relatively low stiffness of the fasteners 124 can be problematic during shock events, which can generate relatively large forces based on the relatively large mass of many heatsinks. Specifically, such fasteners 124 will be too soft to absorb shock-induced forces (e.g., the shock load 102) by themselves. As a result, the shock load 102 may end up passing substantially, if not entirely, through the IC package 104 unless there is some other mechanism for securing the relatively high-mass heatsink 106 relative to the rest of the component stack 100. Accordingly, in the illustrated example, the heatsink 106 is coupled to the bolster plate 110 and/or the backplate 112 via one or more mechanical locks 126. As shown in FIG. 1, the mechanical locks 126 are distinct from and operate independent of the spring-loaded fasteners 124. As used in this context, the mechanical locks 126 operating “independent” of the spring-loaded fasteners means the mechanical locks 126 can be tightened, loosened, and/or otherwise adjusted independent of (e.g., separate from) the tightening, loosening, and/or otherwise adjusting of the spring-loaded fasteners 124. In other words, the mechanical locks 126 are able to secure the heatsink 106 in position relative to the bolster plate 110 and/or the backplate 112 without reliance on the spring-loaded fasteners 124.

In some examples, the mechanical locks 126 are constructed to be relatively stiff (e.g., stiffer than the spring-loaded fasteners 124) to withstand shock-induced forces. In other words, the mechanical locks 126 provide a path for the shock load 102 that is separate from the IC package 104. Thus, as shown in FIG. 1, the shock load 102 on the component stack 100 can be distributed between a first portion 128 that passes through the IC package 104 and one or more second portions 130 that pass through the mechanical locks 126. In some examples, the mechanical locks 126 are stiffer than the TIM 122 and/or the IC package 104 such that second portions 130 of the shock load 102 are greater than the first portion 128. As a result, there is less concern of stress and/or damage occurring to the solder joints of the BGA 120 than is the case with known component stacks that rely exclusively on spring-loaded fasteners to absorb shock-induced forces. As such, examples disclosed herein enable the implementation of larger (e.g., heavier) heatsinks 106 than is otherwise possible using known techniques, thereby enhancing the efficiency and/or capacity of the thermal management solution. In some examples, the mechanical locks 126 are constructed to restrain movement of the heatsink in six degrees of freedom (e.g., restrain translation along three orthogonal axes relative to the PCB 108, and restrain rotational movement about the three orthogonal axes relative to the PCB 108). As such, in some examples, the mechanical locks 126 can help absorb any type of shock load. Moreover, by separating the mechanism to restrain the heatsink 106 during a shock event from the mechanism to compress the TIM 122 (rather than relying on the spring-loaded fasteners 124 for both functions), the spring-loaded fasteners 124 can be tuned specifically to provide the proper amount of loading for more efficient heat transfer.

In some examples, the mechanical locks 126 are adjustable to secure the heatsink 106 relative to the PCB 108 at different positions depending on where the heatsink 106 needs to be under normal operations for improved (e.g., optimal) compression on the IC package 104 (with the TIM 122 therebetween). That is, in some examples, the mechanical locks 126 can be tightened and released (e.g., locked and unlock) independent of the spring-loaded fasteners 124. Accordingly, in some examples, the spring-loaded fasteners 124 can be tightened to a desired extent while the mechanical locks 126 are released. Once the spring-loaded fasteners 124 have been tightened, the mechanical locks 126 are tightened to secure the heatsink 106 at the particular position initially set by the spring-loaded fasteners 124. Thus, the mechanical locks 126 are examples of means for locking the heatsink 106 in place relative to the IC package 104.

FIG. 2 illustrates an example component stack 200 corresponding to a first example implementation of the component stack 100 of FIG. 1. Accordingly, the same reference numbers are used in FIG. 2 as in FIG. 1 to identify the same or similar components and the corresponding description provided in connection with FIG. 1 applies equally to FIG. 2 except as otherwise noted or made clear from the context. Thus, as shown in FIG. 2, the example component stack 200, includes a heatsink 106 positioned over an IC package 104 (not visible in the figure) on a PCB 108 with a bolster plate 110 surrounding the IC package 104. Further, in some examples, a backplate 112 is positioned on the opposite side of the PCB 108. Spring-loaded fasteners 124 place the entire stack 200 in compression. In this example, a separate spring-loaded fastener 124 is located adjacent each corner of the heatsink 106.

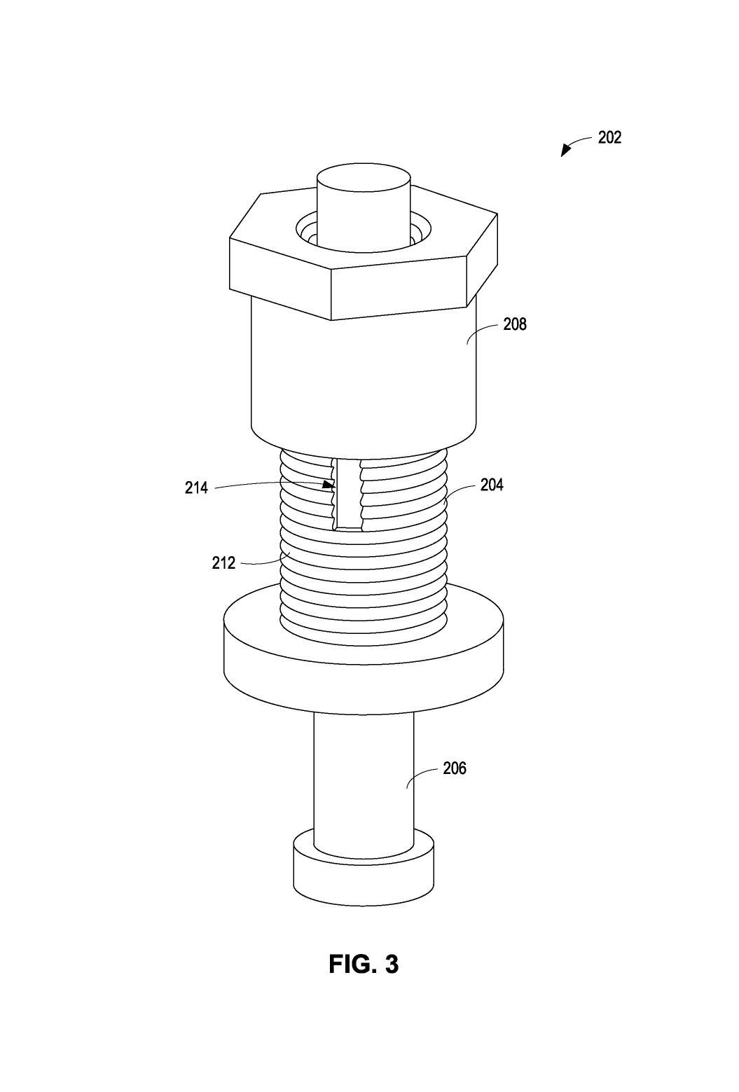

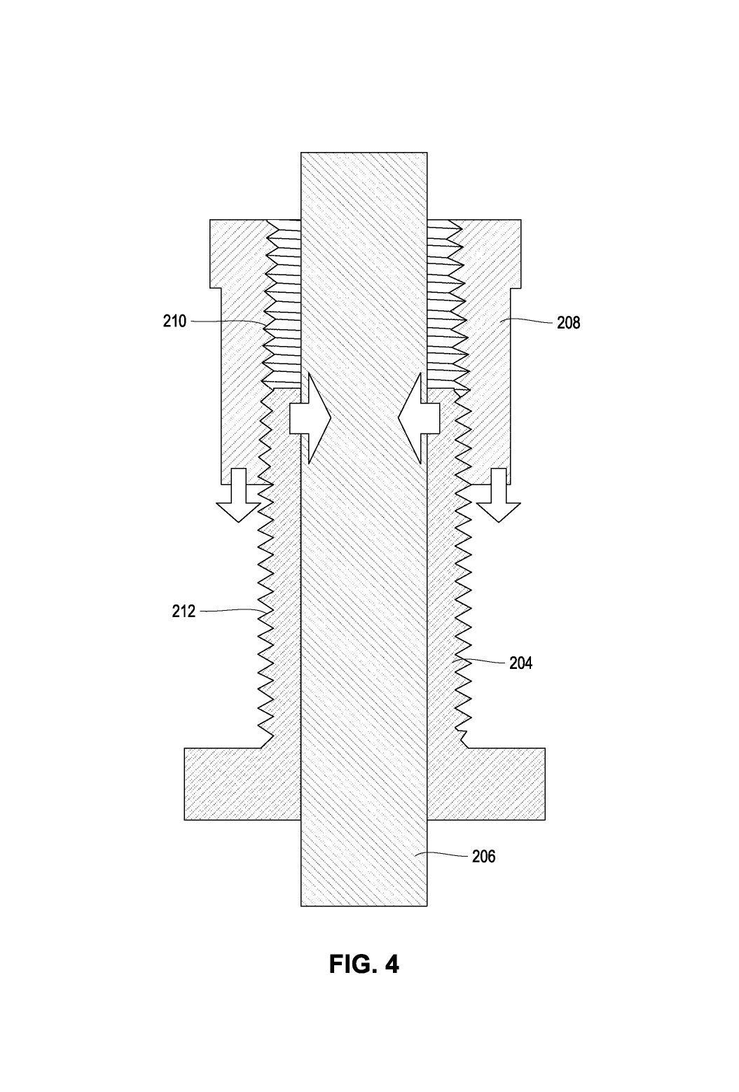

In the illustrated example of FIG. 2, a separate mechanical lock 202 (e.g., means for locking the heatsink 106 in place relative to the IC package 104) is provided adjacent each one of the spring-loaded fasteners 124. The mechanical locks 202 of FIG. 2 are a first example implementation of the mechanical locks 126 schematically represented in FIG. 1. FIG. 3 is an enlarged view of one of the example mechanical locks 202 shown in FIG. 2. FIG. 4 is a cross-sectional view of one of the example mechanical locks 202 shown in FIG. 2.

In the example shown in FIG. 2, the mechanical locks 202 are closer to the corners of the heatsink 106 than the spring-loaded fasteners 124 are to the corners. That is, in this example, the spring-loaded fasteners 124 are closer to a center of the heatsink 106 than the mechanical locks 202 are to the center of the heatsink 106. In other examples, the mechanical locks 202 are closer to the center of the heatsink 106 than the spring-loaded fasteners 124 are to the center of the heatsink 106. In some such examples, the mechanical locks 202 are still proximate to the spring-loaded fasteners 124. In other examples, the mechanical locks 202 may be spaced farther apart (e.g., proximate a midpoint between two of the spring-loaded fasteners 124). In this example, the number of mechanical locks 202 corresponds to the number of spring-loaded fasteners 124. In other examples, the number of mechanical locks 202 is greater than the number of spring-loaded fasteners 124 (e.g., each fastener 124 is flanked on either side by a separate lock 202, there are two locks 202 distributed along the long sides of the heatsink 106 and one lock on each of the short sides, etc.). In other examples, the number of mechanical locks 202 is less than the number of spring-loaded fasteners 124 (e.g., there are only two locks 202 on opposing sides of the heatsink 106). In some examples, there is only mechanical lock 202.

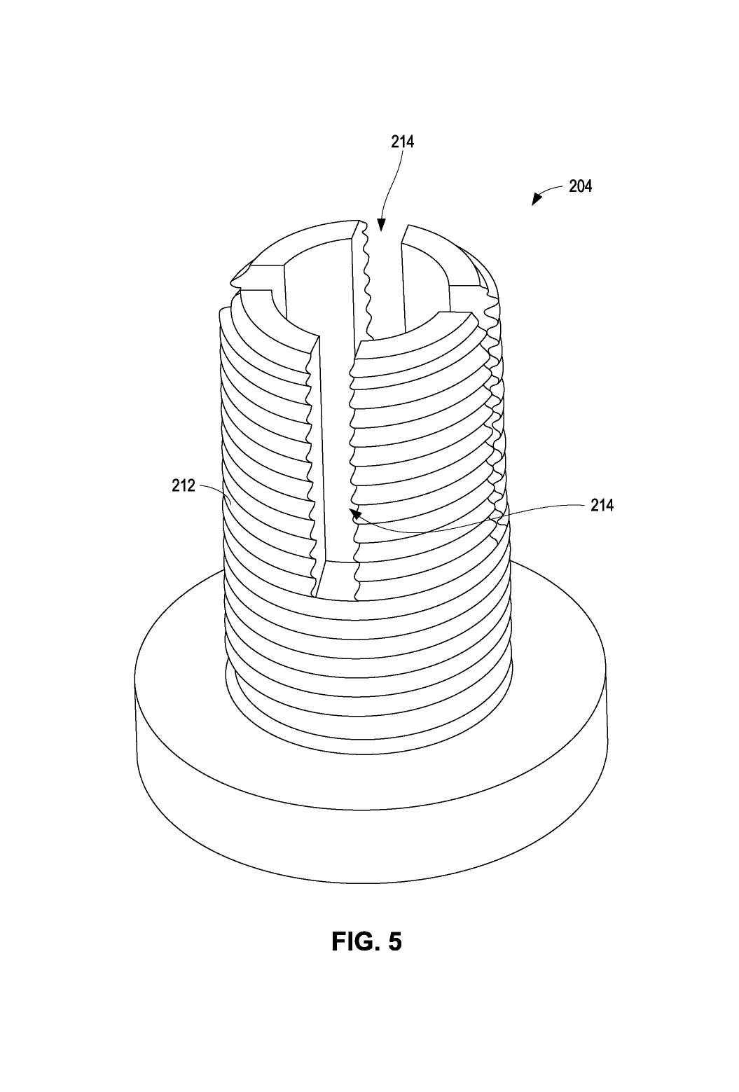

In the illustrated example of FIG. 2, the mechanical locks 202 include a locking collar 204 that fits over a stud or post 206 and is secured in place with a locking nut 208 that surrounds the locking collar 204. In this example, the post 206 is rigidly connected to the bolster plate 110 and extends upward from the PCB 108 through an opening in a base of the heatsink 106. Thus, the post 206 is an example of a means for spanning a distance between the bolster plate 110 and the heatsink 106 to provide a rigid connection between the components that is independent of (e.g., bypasses) the IC package 104 and the spring-loaded fasteners 124. In some examples, the post 206 is an integral extension of the bolster plate 110. In other examples, the post 206 is connected to the bolster plate 110 in any other suitable manner (e.g., threads, press-fitting, an adhesive, welding, etc.). In some examples, the post 206 is rigidly connected to the backplate 112 in addition to or instead of the bolster plate 110. In some such examples, the post 206 extends through openings (e.g., holes) in the PCB 108 and the bolster plate 110. In some examples, the post 206 is relatively smooth along its length. In other examples, at least the portion of the post 206 that interfaces with the locking collar 204 includes threads, ribs, ridges, and/or an otherwise roughened surface to increase friction between the post 206 and the locking collar 204. FIG. 5 is an enlarged view of the example locking collar 204 of FIGS. 2-4.

In some examples, the locking collar 204 is dimensioned to provide a relatively tight clearance fit for the post 206 to extend therethrough. The clearance fit enables the post 206 to freely move through the locking collar 204 when the spring-loaded fasteners 124 are being loaded. However, the clearance fit is relatively tight so that the locking collar 204 can be clamped against the post 206 when the locking nut 208 is tightened thereon. In other examples, the locking collar 204 is dimensioned to provide a relatively loose interference fit with the post 206. In some such examples, the locking collar 204 is constructed to be sufficiently flexible to still allow the post 20 to freely move with relatively little force despite the interference fit (at least until the locking collar 204 is tightened by the locking nut 208). By dimensioning the locking collar 204 to allow free axial movement relative to the post 206 (whether by a clearance fit or a slight interference fit), the mechanical lock 202 does not affect the process of loading the spring-loaded fasteners 124, which are to be tightened before the mechanical lock 202 is tightened. However, as represented by the arrows in FIG. 4, when the locking nut 208 is threaded onto the locking collar 204 to tighten the mechanical lock 202, the locking nut 208 compresses the collar 204 against the post 206 to lock the collar 204 in place based on friction. More particularly, in this example, the locking nut 208 includes inner threads 210 that are tapered to urge the locking collar 204 inwards toward the post 206 as the locking nut 208 is tightened around exterior threads 212 on the collar 204. Thus, the collar 204 is an example of a means for gripping the post 206, and the locking nut 208 is an example of a means for tightening the collar 204.

In some examples, whether tightened around the post 206 or not, the locking collar 204 is rigidly affixed to the heatsink 106. Thus, when the locking nut 208 locks the collar 204 against the post 206, the heatsink 106 effectively becomes locked in placed relative to the bolster plate 110 (and/or backplate 112) with fixed connections between the heatsink 106 and the locking collar 204, between the locking collar 204 and the post 206 (by virtue of the locking nut 208), and between the post 206 and the bolster plate 110 (and/or backplate 112). In some examples, the locking collar 204 is affixed to the heatsink 106 via the threads 212 on the exterior of the locking collar 204. That is, in some examples, the locking collar 204 is attached to the heatsink 106 via a threaded hole in the heatsink 106. Additionally or alternatively, in some examples, the locking collar 204 is affixed to the heatsink 106 using any other suitable method (e.g., press-fitting, adhesive, etc.). The fixed spatial relationship established between the heatsink 106 and the backplate 112 via the locked connections set forth above provides a load path for shock-induced forces that is separate from (e.g., independent of) the IC package 104 against which the heatsink 106 is pressed by the spring-loaded fasteners 124. Accordingly, the mechanical locks 202 help protect the IC package 104 from experiencing stress and/or incurring damage due to a shock event.

In some examples, the locking collar 204 is constructed to radially compress and clamp onto (e.g., grip, bind to) the post 206. In some examples, this is achieved by fabricating the locking collar 204 out of a high strength polymer that is capable of flexing. In other examples, a different material (e.g., metal) can be used for the locking collar 204. In some examples, the locking collar 204 includes one or more cutout 214 (e.g., notch, slot, etc.) that extends through the wall of the locking collar 204 at the end that is to be engaged by the locking nut 208. The one or more cutout 214 can help make the collar 204 more flexible to facilitate the radially compression of the locking collar 204 with the need for less torque being applied to the locking nut 208.

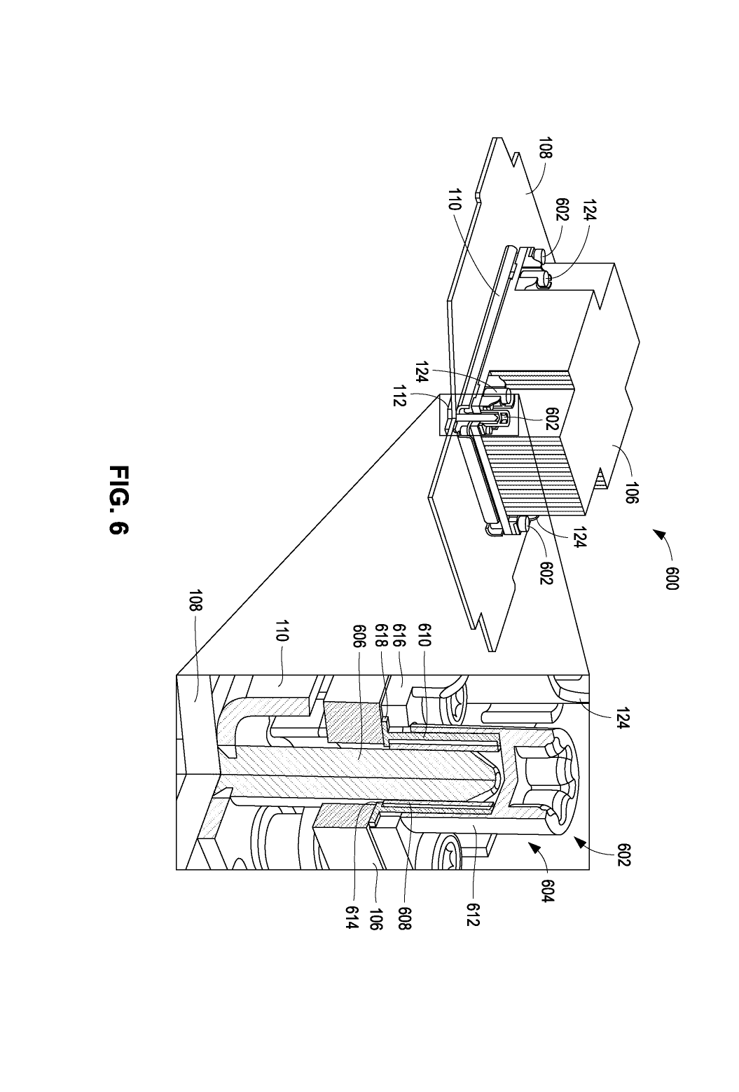

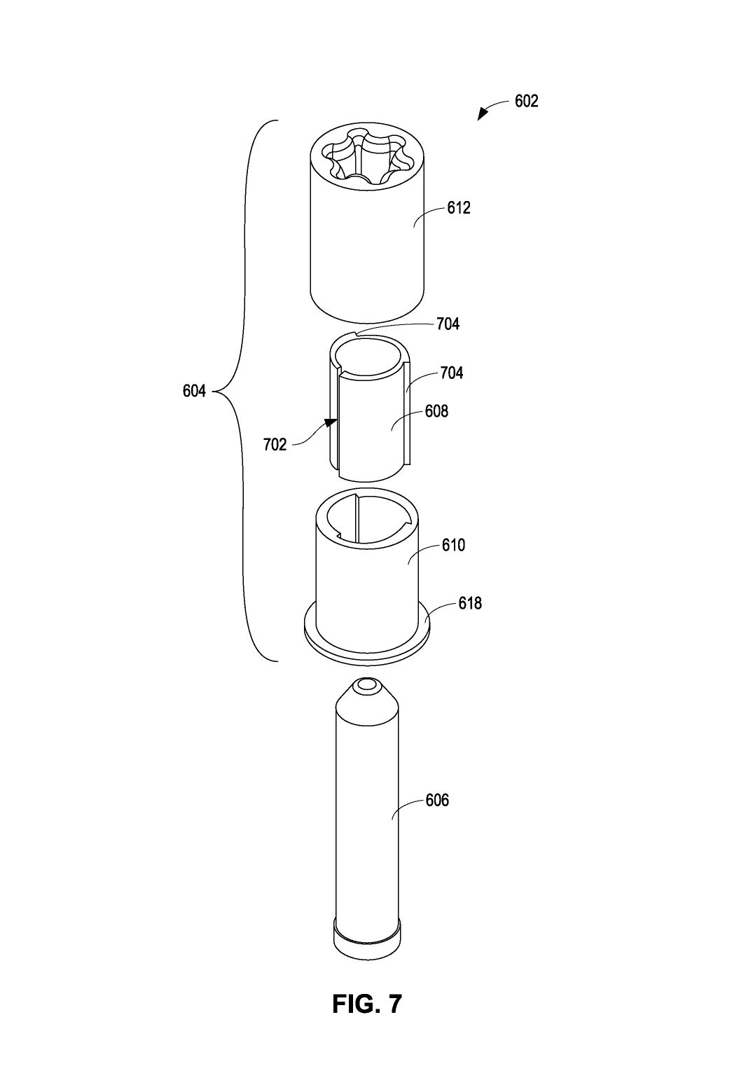

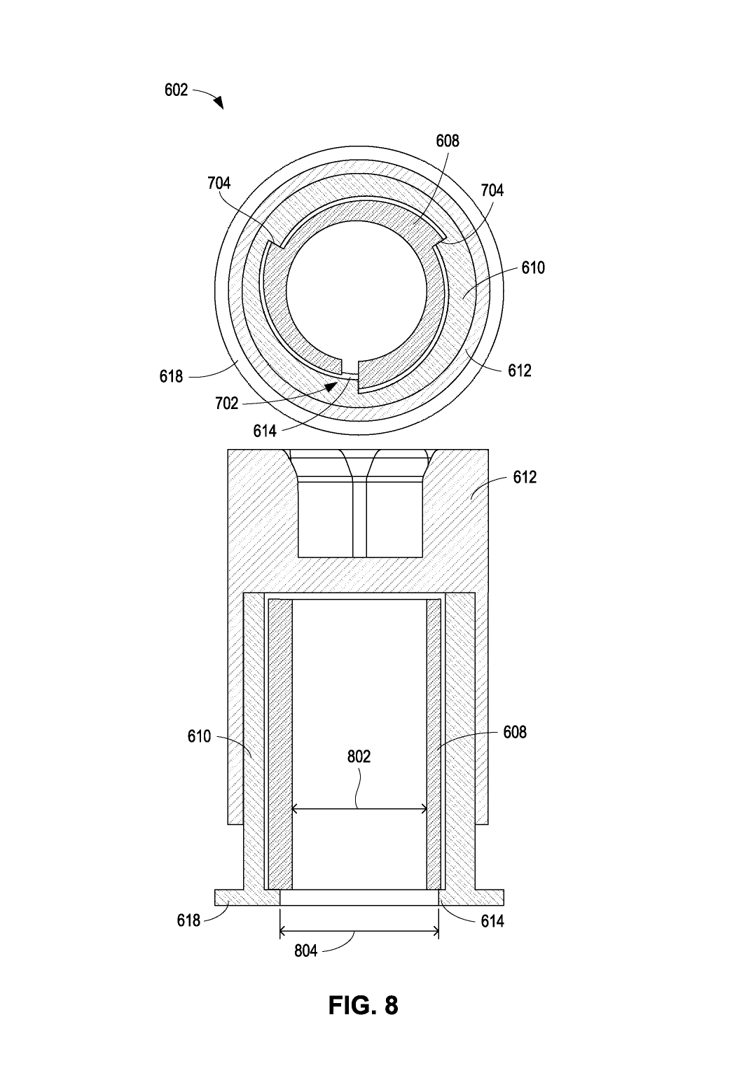

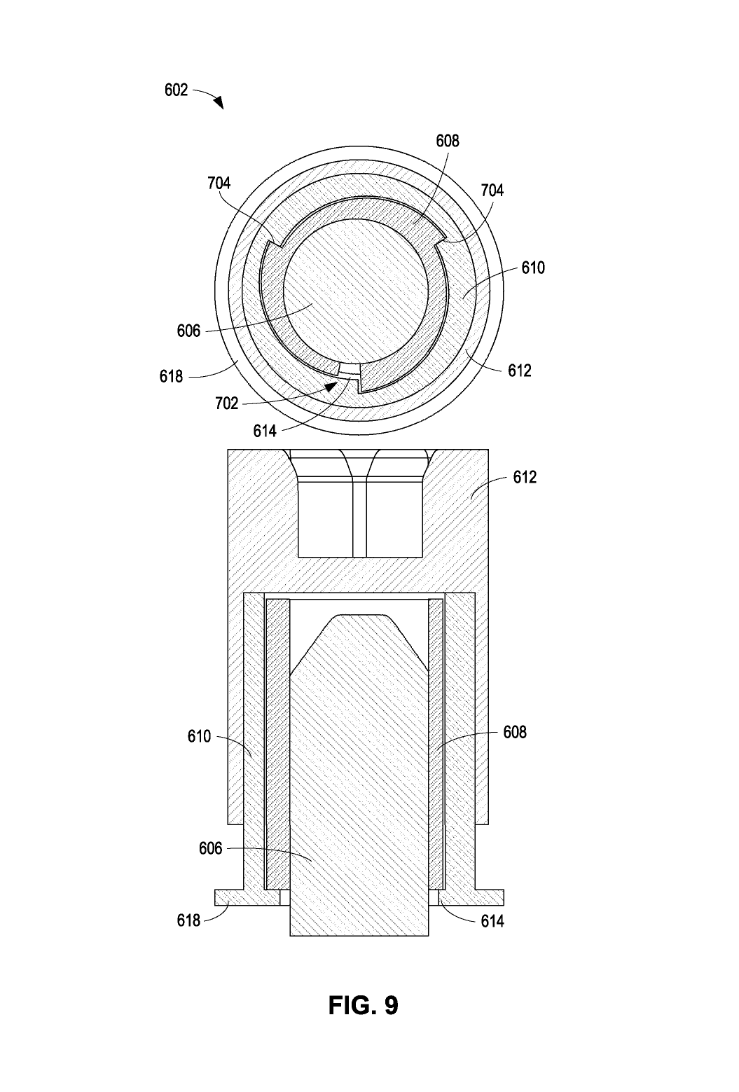

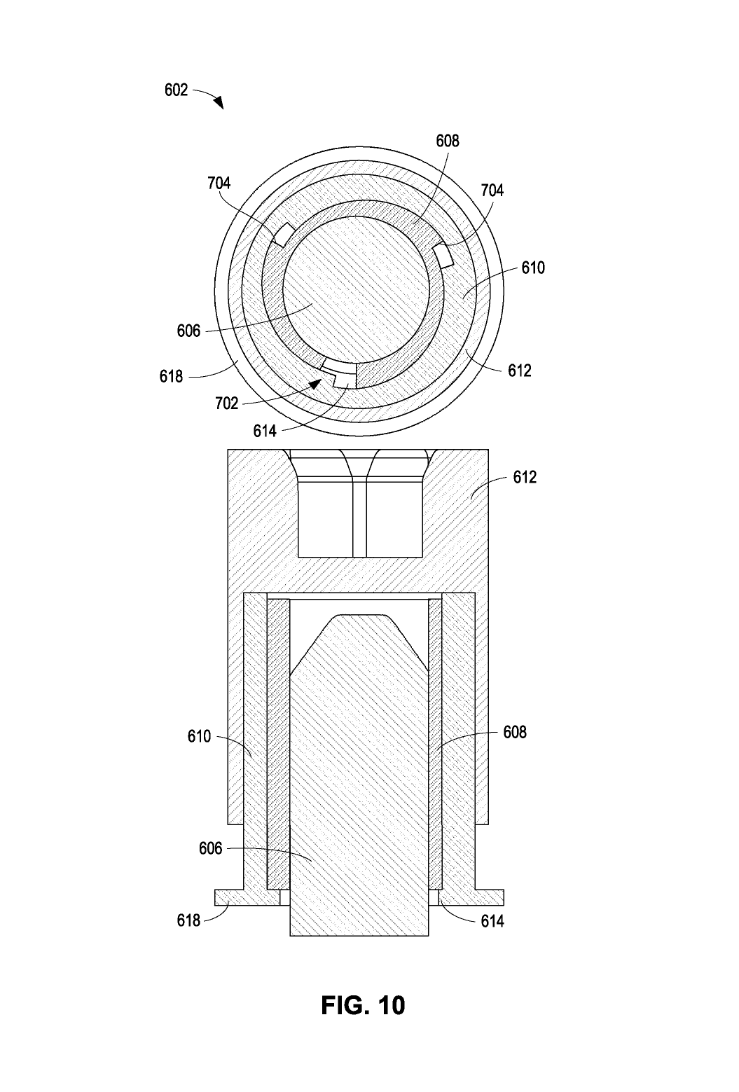

FIG. 6 illustrates an example component stack 600 corresponding to a second example implementation of the component stack 100 of FIG. 1. Accordingly, the same reference numbers are used in FIG. 6 as in FIG. 1 to identify the same or similar components and the corresponding description provided in connection with FIG. 1 applies equally to FIG. 6 except as otherwise noted or made clear from the context. Thus, as shown in FIG. 6, the example component stack 600, includes a heatsink 106 positioned over an IC package 104 (not visible in the figure) on a PCB 108 with a bolster plate 110 surrounding the IC package 104. Further, in some examples, a backplate 112 is positioned on the opposite side of the PCB 108. Spring-loaded fasteners 124 place the entire stack 600 in compression. In this example, a separate mechanical lock 602 (e.g., means for locking the heatsink 106 in place relative to the IC package 104) is provided adjacent each one of the spring-loaded fasteners 124. The mechanical locks 602 of FIG. 6 are a second example implementation of the mechanical locks 126 schematically represented in FIG. 1. FIG. 7 is an exploded view of one of the example mechanical locks 602 shown in FIG. 6. FIGS. 8-10 each show a cross-sectional top view and a cross-sectional side view of the example mechanical lock 602 shown in FIG. 7 at different stages of assembly. Specifically, FIG. 8 illustrates an example locking collar assembly 604 of the mechanical lock 602 in a free state before being coupled to a stud or post 606 (e.g., means for spanning a distance between the bolster plate 110 and the heatsink 106). FIG. 9 illustrates the example locking collar assembly 604 after being coupled to the post 606 but before being tightened. FIG. 10 illustrates the example locking collar assembly 604 after being tightened on the post 606.

While the illustrated example of FIG. 6 shows the spring-loaded fasteners 124 and the mechanical locks 602 in a particular arrangement, different arrangements are possible. That is, the component stack 600 can include any suitable number of mechanical locks 602 positioned at any suitable location. In other words, the discussion of the number and locations of the mechanical locks 202 provided above in connection with FIG. 2 applies equally to the mechanical locks 602 shown in FIG. 6 except as otherwise noted or made clear from the context.

In the illustrated example of FIG. 6, the mechanical lock 602 includes a locking collar assembly 604 that fits over and clamps onto (e.g., grips, binds to) the post 606 when tightened. The post 606 of FIG. 6 may be the same as or similar to the post 206 of FIG. 2. Thus, the description of the post 206 provided above in connection with FIG. 2 applies equally to the post 606 shown in FIG. 6 except as otherwise noted or made clear from the context.

In this example, the locking collar assembly 604 includes a collar 608 (e.g., means for gripping the post 206) contained with a nut bottom 610, which is contained within a nut top 612. The nut bottom 610 and nut top 612 define different portions of a locking nut corresponding to another example means for tightening the collar 204. In some examples, the nut bottom 610 and the nut top 612 are rigidly affixed together with the collar 608 captivated therebetween. The nut bottom 610 and the nut top 612 can be affixed together in any suitable manner (e.g., threads, press-fitting, an adhesive, welding, etc.). As shown in the illustrated example, the collar 608 is retained inside the nut bottom 610 at the top side by the nut top 612 that extends over the top opening in the nut bottom 610. The collar 608 is retained inside the nut bottom 610 at the bottom side by an inner lip 614 that protrudes radially inward from the main sidewalls of the nut bottom 610. In some examples, the collar 608 has a first inner dimension 802 (labelled in FIG. 8) that is less than a second inner dimension 804 defined by the inner lip 614. That is, the collar 608 protrudes more inwardly than the inner lip 614 of the nut bottom 610. The collar 608 can be fabricated from any suitable material (e.g., metal, high strength polymer, etc.).

In some examples, the first inner dimension 802 of the collar 608 is defined to generally correspond to the diameter of the post 606. That said, in some examples, the collar 608 includes a slot 702 extending a full axial length of the collar 708 to provide flexibility to expand and contract (thus, affecting the size of the first inner dimension 802). The flexible nature of the collar 608, with the first inner dimensions 802 generally corresponding to the diameter of the post 606, enables the post 606 to freely move relative to the collar 608 so long as the collar 608 is not tightened around the post 606. In this manner, the mechanical lock 602 does not affect the process of loading the spring-loaded fasteners 124, which are to be tightened before the mechanical lock 602 is tightened. However, when the mechanical lock 602 is tightened, the locking collar 608 is compressed against the post 606 to lock in place based on friction.

In some examples, the slot 702 extends only part way along the length of the collar 608 (e.g., similar to the cutouts 214 shown in FIGS. 2-5). In other examples, the slot 702 is omitted. In some such examples, the flexibility of the collar 608 is based on the material used to fabricate the collar 608 (e.g., a flexible high strength polymer).

In the illustrated example of FIGS. 6-10, the collar 608 can be selectively tightened by rotation of the nut bottom 610 and nut top 612 (that are rigidly connected to move as a unit) to interact with circumferential ramp features on the exterior of the collar 608. That is, in this example, the collar 608 includes a wall that increases in radial thickness between different points (like a ramp or wedge) about a circumference of the collar 608. In some examples, the wall thickness increases continuously about the entire circumference from a first (thinnest) point on the first side of the slot 702 to a second (thickest) point on the opposite side of the slot 702. In other examples, the wall thickness increases continuously between points corresponding to segments of the circumference that are less than the entire way around the collar 608. For instance, as shown in FIGS. 7-10, the wall of the collar 608 increases from a thin wall to a thick wall across three separate segments demarcated by two discontinuities 704 where the wall thickness transitions from a thickest point to a thinnest point. In other examples, the exterior wall can be separated into any other suitable number of segments that ramp from a thinnest point to a thickest point.

In some examples, as most clearly shown in FIG. 7, the inner surface of the wall of the nut bottom 610 is dimensioned to generally match and/or conform to the exterior shape of the collar 608. That is, the inner surface of the nut bottom 610 is shaped with a wall having a thickness that varies along the circumference in a way that is complementary to the collar 608 to accommodate the ramp-like circumferential profile of the collar 608 and any discontinuities 704 between different segments of the circumference of the collar 608. In this example, when the exterior surface of the collar 608 is aligned with the corresponding inner surface of the nut bottom 610, the inner surface of the collar 608 is generally circular (as shown in FIG. 8) and dimensioned to enable the post 606 to pass freely therethrough (as shown in FIG. 9) due to a slight clearance between the adjacent components. However, when the nut bottom 610 is rotated (e.g., by torquing the nut top 612) relative to the collar 608 (as shown in FIG. 10), thicker portions of the wall of the nut bottom 610 are rotated into contact with thicker portions of the wall of the collar 608, thereby eliminating the clearance between the components. As a result, the collar 608 is urged toward the post 606 until there is sufficient friction to secure the locking collar assembly 604 in place relative to the post 606.

In some examples, whether tightened around the post 606 or not, the locking collar assembly 604 is held in fixed relationship to the heatsink 106. Thus, when the collar 608 is tightened against the post 606, the heatsink 106 effectively becomes locked in placed relative to the bolster plate 110 (and/or backplate 112) in a similar manner to what was discussed above in connection with FIGS. 2-5. As a result, the fixed spatial relationship established between the heatsink 106 and the backplate 112 provides a load path for shock-induced forces that is separate from (e.g., independent of) the IC package 104 against which the heatsink 106 is pressed by the spring-loaded fasteners 124. Accordingly, the mechanical locks 602 help protect the IC package 104 from experiencing stress and/or incurring damage due to a shock event. In this example, the locking collar assembly 604 is held in fixed relationship to the heatsink by a brace 616 that overlaps and captures an outer lip 618 (e.g., outer flange) at the base of the nut bottom 610. In some examples, the brace overlaps the outer lip 618 with a clearance fit to enable the nut bottom 610 to rotate (with the nut top 612) relative to the heatsink 106 to selectively tighten or loosen the collar 608 around the post 606.

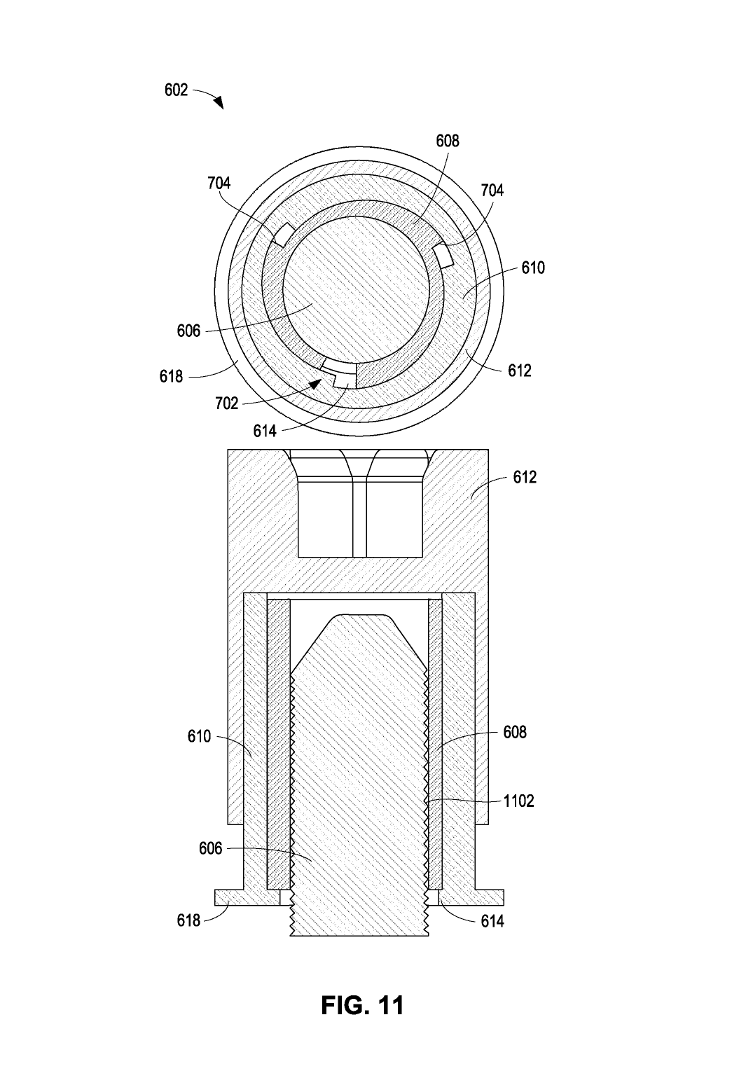

FIG. 11 illustrates a variation to the example mechanical lock 602 shown in FIGS. 7-10. Specifically, the example of FIG. 11 differs from the example shown in FIGS. 7-10 in that the post 606 includes threads, ribs, ridges, and/or an otherwise roughened surface 1102 to provide additional resistance (e.g., friction) to axial movement between the post 606 and the collar 608 when the collar 608 is clamped tight around the post 606. Such threads, ribs, ridges, and/or an otherwise roughened surface 1102 could additionally or alternatively be implemented on the post 206 in the illustrated example of FIGS. 2-5.

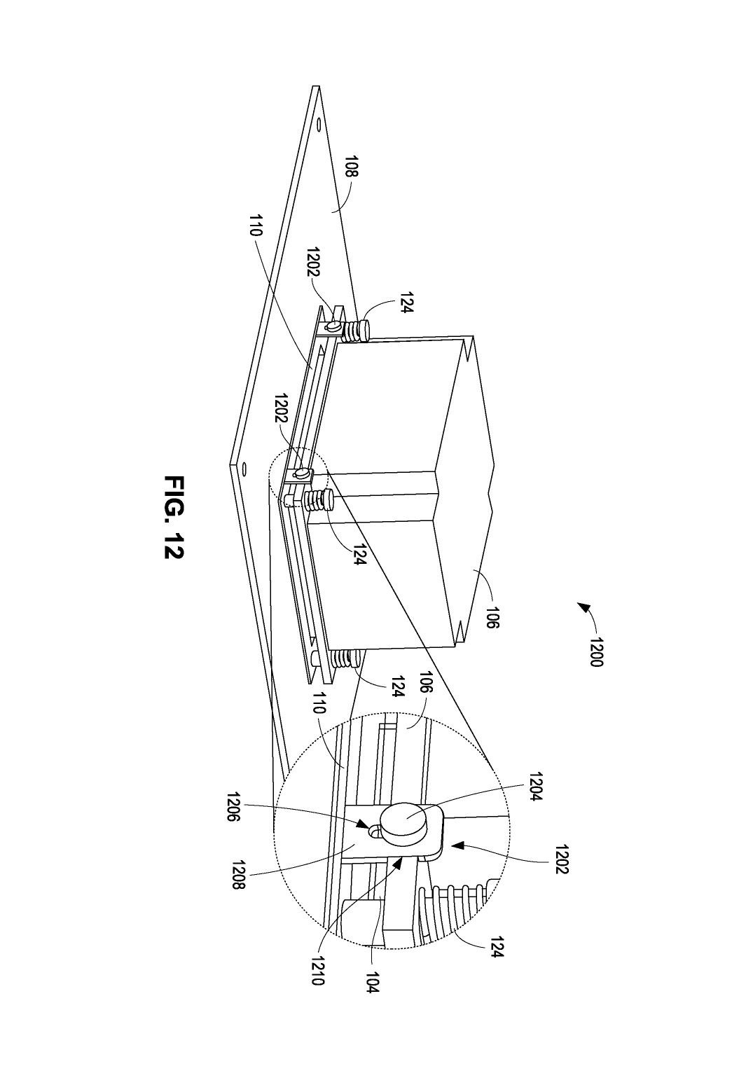

FIG. 12 illustrates an example component stack 1200 corresponding to a third example implementation of the component stack 100 of FIG. 1. Accordingly, the same reference numbers are used in FIG. 12 as in FIG. 1 to identify the same or similar components and the corresponding description provided in connection with FIG. 1 applies equally to FIG. 12 except as otherwise noted or made clear from the context. Thus, as shown in FIG. 12, the example component stack 1200, includes a heatsink 106 positioned over an IC package 104 on a PCB 108 with a bolster plate 110 surrounding the IC package 104. Further, in some examples, a backplate 112 (not visible in the figure) is positioned on the opposite side of the PCB 108. Spring-loaded fasteners 124 place the entire stack 1200 in compression. In this example, a separate mechanical lock 1202 (e.g., means for locking the heatsink 106 in place relative to the IC package 104) is provided adjacent each one of the spring-loaded fasteners 124. The mechanical locks 1202 of FIG. 12 are a third example implementation of the mechanical locks 126 schematically represented in FIG. 1.

While the illustrated example of FIG. 12 shows the spring-loaded fasteners 124 and the mechanical locks 1202 in a particular arrangement, different arrangements are possible. That is, the component stack 1200 can include any suitable number of mechanical locks 1202 positioned at any suitable location. In other words, the discussion of the number and locations of the mechanical locks 202 provided above in connection with FIG. 2 applies equally to the mechanical locks 1202 shown in FIG. 12 except as otherwise noted or made clear from the context.

In the illustrated example of FIG. 12, the mechanical lock 1202 includes a locking screw 1204 that fits through an elongated slot 1206 in a tab or flange 1208 (e.g., means for spanning a distance between the bolster plate 110 and the heatsink 106) that protrudes upwards from the bolster plate 110 (e.g., extends transverse to the PCB 108). In some examples, the flange 1208 is rigidly coupled to the bolster plate 110. In some examples, the flange 1208 is an integral extension of the bolster plate 110. In some examples, the flange is rigidly coupled to and/or an integral extension of the backplate 112 instead of the bolster plate 110. In some examples, as shown in the enlarged inset image of FIG. 12, the flange 1208 is positioned to fit within a notch 1210 in a side edge of the heatsink 106. In other examples, the flange 1208 is positioned adjacent an outer surface of the side edge of the heatsink 106 and the notch 1210 is omitted.

In some examples, the heatsink 106 includes a threaded hole that extends inward from the side edge of the heatsink 106 and that aligns with the elongated slot 1206. In this example, the elongated slot 1206 has a height and length that extends across the full expected travel distance of the threaded hole in the heatsink 106 as the heatsink 106 is pressed against the IC package 104 by tightening the spring-loaded fasteners 124. In this manner, the threaded hole will remain accessible through the elongated slot 1206 in the flange 1208 after the spring-loaded fasteners 124 are tightened. As such, once the spring-loaded fasteners 124 have been tightened, the locking screw 1204 can be inserted into the threaded hole through the elongated slot 1206 and tightened to provide a fixed connection from the heatsink 106 to the bolster plate 110 (and/or the backplate 112) that is independent of the IC package 104. Thus, the locking screw 1204 is an example of a means for fastening the flange 1208 to the heatsink 106.

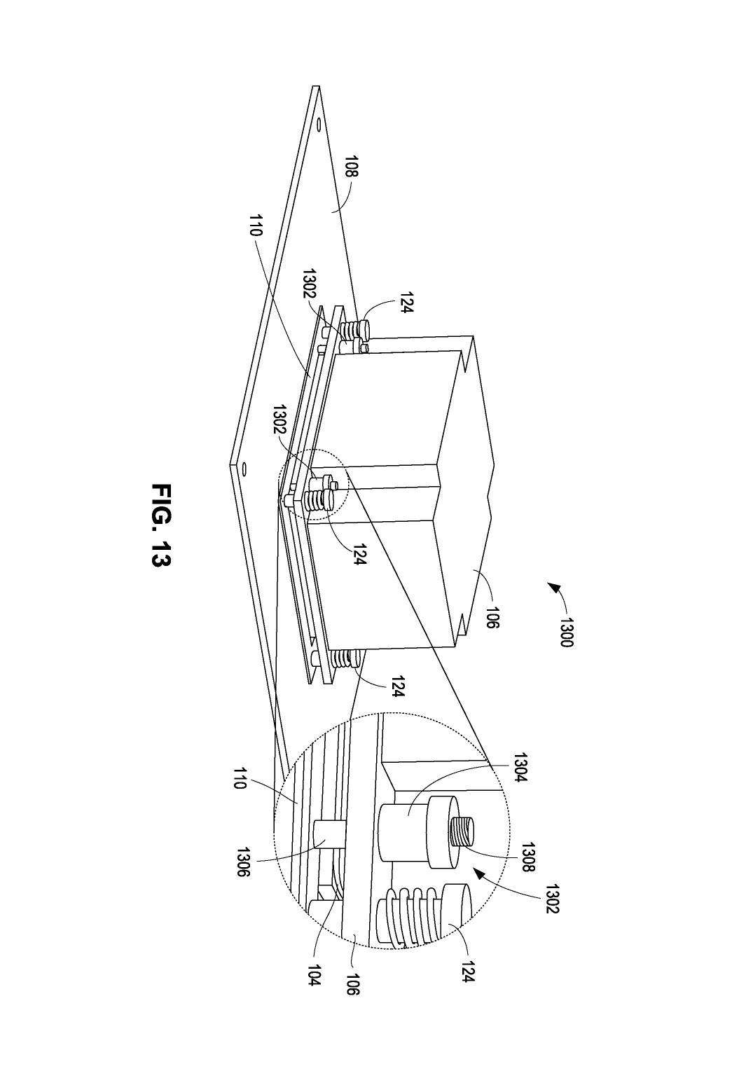

FIG. 13 illustrates an example component stack 1300 corresponding to a fourth example implementation of the component stack 100 of FIG. 1. Accordingly, the same reference numbers are used in FIG. 13 as in FIG. 1 to identify the same or similar components and the corresponding description provided in connection with FIG. 1 applies equally to FIG. 13 except as otherwise noted or made clear from the context. Thus, as shown in FIG. 13, the example component stack 1300, includes a heatsink 106 positioned over an IC package 104 on a PCB 108 with a bolster plate 110 surrounding the IC package 104. Further, in some examples, a backplate 112 (not visible in the figure) is positioned on the opposite side of the PCB 108. Spring-loaded fasteners 124 place the entire stack 1300 in compression. In this example, a separate mechanical lock 1302 (e.g., means for locking the heatsink 106 in place relative to the IC package 104) is provided adjacent each one of the spring-loaded fasteners 124. The mechanical locks 1302 of FIG. 13 are a fourth example implementation of the mechanical locks 126 schematically represented in FIG. 1.

While the illustrated example of FIG. 13 shows the spring-loaded fasteners 124 and the mechanical locks 1302 in a particular arrangement, different arrangements are possible. That is, the component stack 1300 can include any suitable number of mechanical locks 1302 positioned at any suitable location. In other words, the discussion of the number and locations of the mechanical locks 202 provided above in connection with FIG. 2 applies equally to the mechanical locks 1302 shown in FIG. 13 except as otherwise noted or made clear from the context.

In the illustrated example of FIG. 13, the mechanical lock 1302 includes a locking nut 1304 (e.g., means for fastening the flange 1208 to the heatsink 106) that is threadedly attached to a stud or post 1306 (e.g., means for spanning a distance between the bolster plate 110 and the heatsink 106) that protrudes upwards from the bolster plate 110. The post 1306 of FIG. 13 is the same as or similar to the post 206 of FIG. 2. Thus, the description of the post 206 provided above in connection with FIG. 2 applies equally to the post 1306 shown in FIG. 13 except as otherwise noted or made clear from the context. As already suggested above, in this example, the post 1306 includes threads 1308 at the free end of the post 1306 to enable connection with the locking nut 1304. In some examples, the heatsink 106 is pressed down onto the IC package 104 by tightening the spring-loaded fasteners 124. Once the heatsink 106 is secured by the spring-loaded fasteners 124, the locking nut 1304 can be threaded onto the post 1306 until the locking nut 1304 comes into contact with the heatsink 106. Notably, in this example, the mechanical lock 1302, when tightened primarily constrains movement of the heatsink 106 relative to the bolster plate 110 in a direction away from the bolster plate 110. While the example mechanical lock 1302 of FIG. 13 does not provide the same level of constraint in other directions as the other example mechanical locks 202, 602, 1202 discussed above, the example mechanical lock 1302 of FIG. 13 at least constrains movement in the direction of one of the highest risk failure modes. Moreover, the reduced efficiency in constraining the heatsink 106 using the example mechanical locks 1302 of FIG. 13 may be considered a suitable tradeoff in some situations based on the much simpler design of the mechanical locks 1302 relative to the other example mechanical locks 202, 602, 1202 disclosed herein.

The foregoing examples of the component stacks 100, 200, 600, 1200, 1300 and the associated mechanical locks 126, 202, 602, 1202, 1302 of FIGS. 1-13 teach or suggest different features. Although each example component stack 100, 200, 600, 1200, 1300 and the associated mechanical locks 126, 202, 602, 1202, 1302 disclosed above have certain features, it should be understood that it is not necessary for a particular feature of one example to be used exclusively with that example. Instead, any of the features described above and/or depicted in the drawings can be combined with any of the examples, in addition to or in substitution for any of the other features of those examples. One example’s features are not mutually exclusive to another example’s features. Instead, the scope of this disclosure encompasses any combination of any of the features. Furthermore, in some examples, a single component stack can include at least two different types of the example mechanical locks 126, 202, 602, 1202, 1302 disclosed herein.

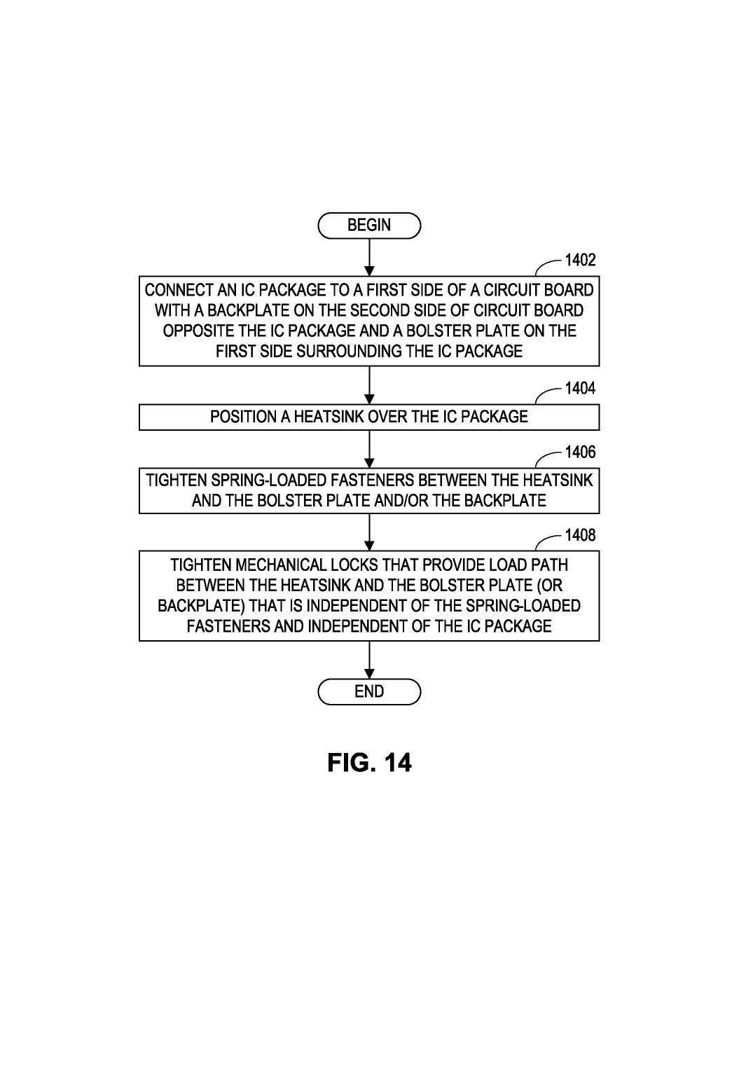

FIG. 14 is a flowchart representative of an example method of assembling any one of the example component stacks 100, 200, 600, 1200, 1300 of FIG. 1-13. In some examples, some or all of the operations outlined in the example method of FIG. 14 are performed automatically by assembly equipment that is programmed to perform the operations. Although the example method of assembly is described with reference to the flowchart illustrated in FIG. 14, many other methods may alternatively be used. For example, the order of execution of the blocks may be changed, and/or some of the blocks described may be combined, divided, re-arranged, omitted, eliminated, and/or implemented in any other way. Further, in some examples, additional processing operations can be performed before, between, and/or after any of the blocks represented in the illustrated example.

The example method of FIG. 14 begins at block 1402 where an IC package (e.g., the IC package 104) is connected to a first side of a circuit board (e.g., the PCB 108) with a backplate (e.g., the backplate 112) on the second side of the circuit board opposite the IC package and a bolster plate (e.g., the bolster plate 110) on the first side surrounding the IC package. In some examples, the IC package is surface mounted to the circuit board via solder bonds. In other examples, the IC package is connected to the circuit board via a socket attached to the circuit board.

At block 1404, the example method involves positioning a heatsink (e.g., the heatsink 106) over the IC package. In some examples, a thermal interface material (e.g., the TIM 122) is disposed between the heatsink and the IC package to facilitate heat transfer.

At block 1406, the example method involves tightening spring-loaded fasteners (e.g., the fasteners 124) between the heatsink and the bolster plate and/or the backplate. In some examples, the spring-loaded fasteners are constructed or tuned with a stiffness that produces a suitable load on the IC package from the heatsink to enhance (e.g., optimize) the heat transfer between the IC package and the heatsink (e.g., across the TIM 122).

At block 1408, the example method involves tightening mechanical locks (e.g., the locks 126, 202, 602, 1202, 1302) that provide a load path between the heatsink and the bolster plate that is independent of the spring-loaded fasteners and independent of the IC package. In some examples, the load path extends from the heatsink to the backplate instead of the bolster plate. Significantly, in this example, the mechanical locks are tightened (block 1408) after the spring-loaded fasteners are tightened (block 1406) so that the mechanical locks do not affect the loading of the IC package from the tightening of the spring-loaded fasteners. Once the spring-loaded fasteners have been tightened, the mechanical locks provide a connection between the heatsink and the bolster plate (and/or the backplate) that is stiffer than the spring-loaded fasteners so as to withstand shock loads. Once the mechanical locks are tightened, the example method of FIG. 14 ends.

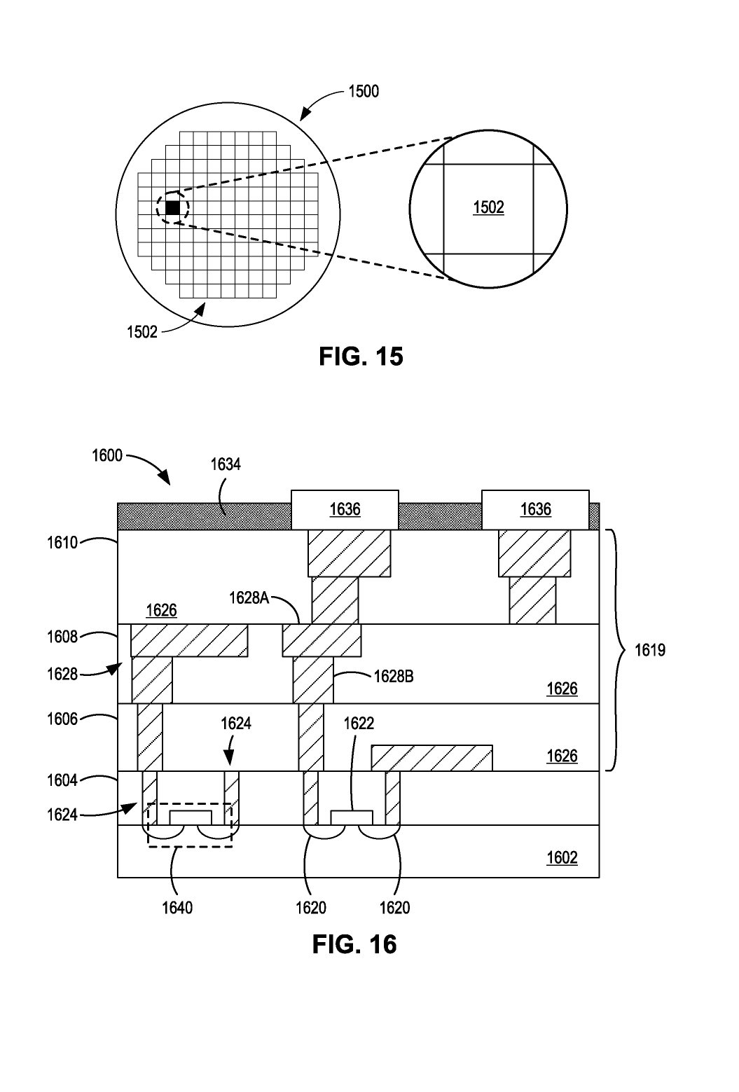

The example component stacks 100, 200, 600, 1200, 1300 and/or the associated mechanical locks 126, 202, 602, 1202, 1302 disclosed herein may be included in any suitable electronic component. FIGS. 15-19 illustrate various examples of apparatus that may include or be included in the example component stack 100, 200, 600, 1200, 1300 disclosed herein.

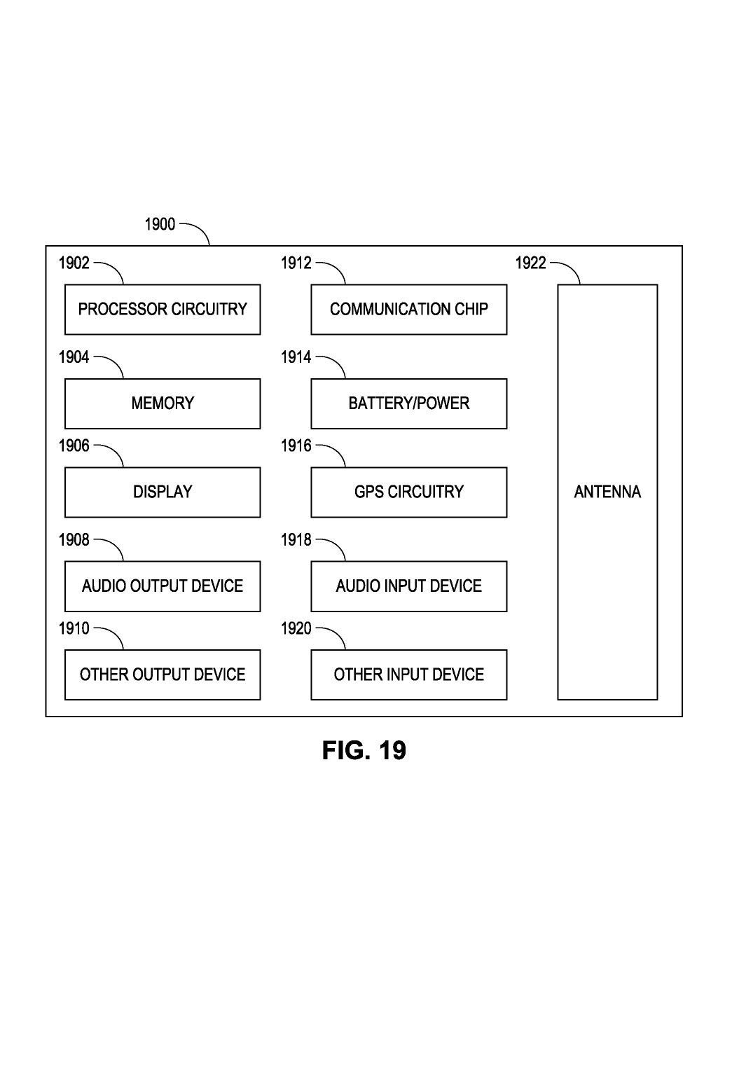

FIG. 15 is a top view of a wafer 1500 and dies 1502 that may be included in the IC package 104 of FIG. 1 (e.g., as any suitable ones of the semiconductor dies 114). The wafer 1500 includes semiconductor material and one or more dies 1502 having circuitry. Each of the dies 1502 may be a repeating unit of a semiconductor product. After the fabrication of the semiconductor product is complete, the wafer 1500 may undergo a singulation process in which the dies 1502 are separated from one another to provide discrete “chips.” The die 1502 includes one or more transistors (e.g., some of the transistors 1640 of FIG. 16, discussed below), supporting circuitry to route electrical signals to the transistors, passive components (e.g., traces, resistors, capacitors, inductors, and/or other circuitry), and/or any other components. In some examples, the die 1502 may include and/or implement a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry or electronics. Multiple ones of these devices may be combined on a single die 1502. For example, a memory array of multiple memory circuits may be formed on a same die 1502 as programmable circuitry (e.g., the processor circuitry 1902 of FIG. 19) and/or other logic circuitry. Such memory may store information for use by the programmable circuitry. The example IC package 104 disclosed herein may be manufactured using a die-to-wafer assembly technique in which some dies are attached to a wafer 1500 that includes others of the dies, and the wafer 1500 is subsequently singulated.

FIG. 16 is a cross-sectional side view of an IC device 1600 that may be included in the example IC package 104 (e.g., in any one of the dies 114). One or more of the IC devices 1600 may be included in one or more dies 1502 (FIG. 15). The IC device 1600 may be formed on a die substrate 1602 (e.g., the wafer 1500 of FIG. 15) and may be included in a die (e.g., the die 1502 of FIG. 15). The die substrate 1602 may be a semiconductor substrate including semiconductor materials including, for example, n-type or p-type materials systems (or a combination of both). The die substrate 1602 may include, for example, a crystalline substrate formed using a bulk silicon or a silicon-on-insulator (SOI) substructure. In some examples, the die substrate 1602 may be formed using alternative materials, which may or may not be combined with silicon, and which include but are not limited to germanium, indium antimonide, lead telluride, indium arsenide, indium phosphide, gallium arsenide, or gallium antimonide. Further materials classified as group II-VI, III-V, or IV may also be used to form the die substrate 1602. Although a few examples of materials from which the die substrate 1602 may be formed are described here, any material that may serve as a foundation for an IC device 1600 may be used. The die substrate 1602 may be part of a singulated die (e.g., the dies 1502 of FIG. 15) or a wafer (e.g., the wafer 1500 of FIG. 15).

The IC device 1600 may include one or more device layers 1604 disposed on and/or above the die substrate 1602. The device layer 1604 may include features of one or more transistors 1640 (e.g., metal oxide semiconductor field-effect transistors (MOSFETs)) formed on the die substrate 1602. The device layer 1604 may include, for example, one or more source and/or drain (S/D) regions 1620, a gate 1622 to control current flow between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 16 and may include a wide variety of other types and/or configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1640 may include a gate 1622 including a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and/or zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and/or lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 1640 is to be a p-type metal oxide semiconductor (PMOS) or an n-type metal oxide semiconductor (NMOS) transistor. In some implementations, the gate electrode may include a stack of two or more metal layers, where one or more metal layers are work function metal layers and at least one metal layer is a fill metal layer. Further metal layers may be included, such as a barrier layer. For a PMOS transistor, metals that may be used for the gate electrode include, but are not limited to, ruthenium, palladium, platinum, cobalt, nickel, conductive metal oxides (e.g., ruthenium oxide), and/or any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and/or aluminum carbide), and/or any of the metals discussed above with reference to a PMOS transistor (e.g., for work function tuning).

In some examples, when viewed as a cross-section of the transistor 1640 along the source-channel-drain direction, the gate electrode may include a U-shaped structure that includes a bottom portion substantially parallel to the surface of the die substrate 1602 and two sidewall portions that are substantially perpendicular to the top surface of the die substrate 1602. In other examples, at least one of the metal layers that form the gate electrode may be a planar layer that is substantially parallel to the top surface of the die substrate 1602 and does not include sidewall portions substantially perpendicular to the top surface of the die substrate 1602. In other examples, the gate electrode may include a combination of U-shaped structures and/or planar, non-U-shaped structures. For example, the gate electrode may include one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and/or silicon oxynitride. Processes for forming sidewall spacers are well known in the art and generally include deposition and etching process operations. In some examples, a plurality of spacer pairs may be used; for instance, two pairs, three pairs, or four pairs of sidewall spacers may be formed on opposing sides of the gate stack.

The S/D regions 1620 may be formed within the die substrate 1602 adjacent to the gate 1622 of corresponding transistor(s) 1640. The S/D regions 1620 may be formed using an implantation/diffusion process or an etching/deposition process, for example. In the former process, dopants such as boron, aluminum, antimony, phosphorus, or arsenic may be ion-implanted into the die substrate 1602 to form the S/D regions 1620. An annealing process that activates the dopants and causes them to diffuse farther into the die substrate 1602 may follow the ion-implantation process. In the latter process, the die substrate 1602 may first be etched to form recesses at the locations of the S/D regions 1620. An epitaxial deposition process may then be carried out to fill the recesses with material that is used to fabricate the S/D regions 1620. In some implementations, the S/D regions 1620 may be fabricated using a silicon alloy such as silicon germanium or silicon carbide. In some examples, the epitaxially deposited silicon alloy may be doped in situ with dopants such as boron, arsenic, or phosphorus. In some examples, the S/D regions 1620 may be formed using one or more alternate semiconductor materials such as germanium or a group III-V material or alloy. In further examples, one or more layers of metal and/or metal alloys may be used to form the S/D regions 1620.

Electrical signals, such as power and/or input/output (I/O) signals, may be routed to and/or from the devices (e.g., transistors 1640) of the device layer 1604 through one or more interconnect layers disposed on the device layer 1604 (illustrated in FIG. 16 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form a metallization stack (also referred to as an “ILD stack”) 1619 of the IC device 1600.

The interconnect structures 1628 may be arranged within the interconnect layers 1606-1610 to route electrical signals according to a wide variety of designs (in particular, the arrangement is not limited to the particular configuration of interconnect structures 1628 depicted in FIG. 16). Although a particular number of interconnect layers 1606-1610 is depicted in FIG. 16, examples of the present disclosure include IC devices having more or fewer interconnect layers than depicted.

In some examples, the interconnect structures 1628 may include lines 1628a and/or vias 1628b filled with an electrically conductive material such as a metal. The lines 1628a may be arranged to route electrical signals in a plane that is substantially parallel with a surface of the die substrate 1602 upon which the device layer 1604 is formed. For example, the lines 1628a may route electrical signals in and/or out of the page from the perspective of FIG. 16. The vias 1628b may be arranged to route electrical signals in a plane that is substantially perpendicular to the surface of the die substrate 1602 upon which the device layer 1604 is formed. In some examples, the vias 1628b may electrically couple lines 1628a of different interconnect layers 1606-1610 together.

The interconnect layers 1606-1610 may include a dielectric material 1626 disposed between the interconnect structures 1628, as shown in FIG. 16. In some examples, the dielectric material 1626 disposed between the interconnect structures 1628 in different ones of the interconnect layers 1606-1610 may have different compositions; in other examples, the composition of the dielectric material 1626 between different interconnect layers 1606-1610 may be the same.

A first interconnect layer 1606 (referred to as Metal 1 or “M1”) may be formed directly on the device layer 1604. In some examples, the first interconnect layer 1606 may include lines 1628a and/or vias 1628b, as shown. The lines 1628a of the first interconnect layer 1606 may be coupled with contacts (e.g., the S/D contacts 1624) of the device layer 1604.

A second interconnect layer 1608 (referred to as Metal 2 or “M2”) may be formed directly on the first interconnect layer 1606. In some examples, the second interconnect layer 1608 may include vias 1628b to couple the lines 1628a of the second interconnect layer 1608 with the lines 1628a of the first interconnect layer 1606. Although the lines 1628a and the vias 1628b are structurally delineated with a line within each interconnect layer (e.g., within the second interconnect layer 1608) for the sake of clarity, the lines 1628a and the vias 1628b may be structurally and/or materially contiguous (e.g., simultaneously filled during a dual-damascene process) in some examples.

A third interconnect layer 1610 (referred to as Metal 3 or “M3”) (and additional interconnect layers, as desired) may be formed in succession on the second interconnect layer 1608 according to similar techniques and/or configurations described in connection with the second interconnect layer 1608 and/or the first interconnect layer 1606. In some examples, the interconnect layers that are “higher up” in the metallization stack 1619 in the IC device 1600 (i.e., further away from the device layer 1604) may be thicker.

The IC device 1600 may include a solder resist material 1634 (e.g., polyimide or similar material) and one or more conductive contacts 1636 formed on the interconnect layers 1606-1610. In FIG. 16, the conductive contacts 1636 are illustrated as taking the form of bond pads. The conductive contacts 1636 may be electrically coupled with the interconnect structures 1628 and configured to route the electrical signals of the transistor(s) 1640 to other external devices. For example, solder bonds may be formed on the one or more conductive contacts 1636 to mechanically and/or electrically couple a chip including the IC device 1600 with another component (e.g., a circuit board). The IC device 1600 may include additional or alternate structures to route the electrical signals from the interconnect layers 1606-1610; for example, the conductive contacts 1636 may include other analogous features (e.g., posts) that route the electrical signals to external components.

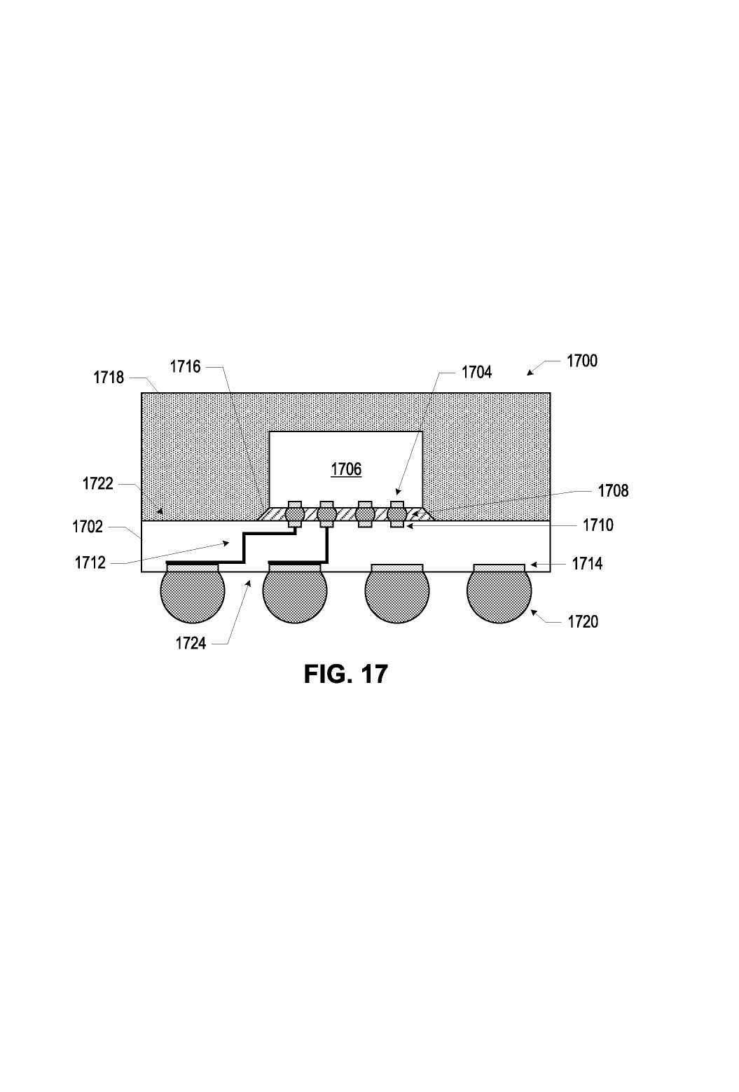

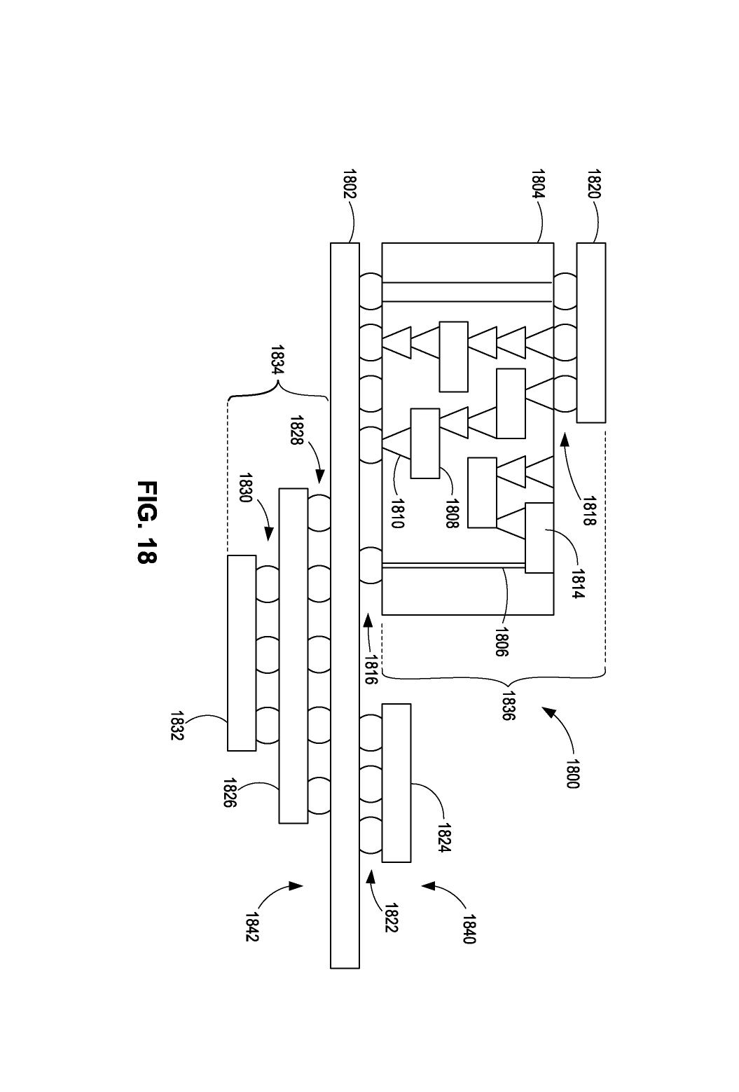

FIG. 17 is a cross-sectional view of an example IC package 1700 that may be used to implement the IC package 104. The package substrate 1702 may include a dielectric material, and may have conductive pathways extending through the dielectric material between upper and lower faces 1722, 1724, and/or between different locations on the upper face 1722, and/or between different locations on the lower face 1724. These conductive pathways may take the form of any of the interconnects 1628 discussed above with reference to FIG. 16.

The IC package 1700 may include a die 1706 coupled to the package substrate 1702 via conductive contacts 1704 of the die 1706, first-level interconnects 1708, and conductive contacts 1710 of the package substrate 1702. The conductive contacts 1710 may be coupled to conductive pathways 1712 through the package substrate 1702, allowing circuitry within the die 1706 to electrically couple to various ones of the conductive contacts 1714 or to other devices included in the package substrate 1702, not shown. The first-level interconnects 1708 illustrated in FIG. 17 are solder bumps, but any suitable first-level interconnects 1708 may be used. As used herein, a “conductive contact” refers to a portion of conductive material (e.g., metal) serving as an electrical interface between different components. Conductive contacts may be recessed in, flush with, or extending away from a surface of a component, and may take any suitable form (e.g., a conductive pad or socket).

In some examples, an underfill material 1716 may be disposed between the die 1706 and the package substrate 1702 around the first-level interconnects 1708, and/or a mold compound 1718 may be disposed around the die 1706 and in contact with the package substrate 1702. In some examples, the underfill material 1716 may be the same as the mold compound 1718. Example materials that may be used for the underfill material 1716 and the mold compound 1718 are epoxy mold materials, as suitable. Second-level interconnects 1720 may be coupled to the conductive contacts 1714. The second-level interconnects 1720 illustrated in FIG. 17 are solder balls (e.g., for a ball grid array arrangement), but any suitable second-level interconnects 1720 may be used (e.g., pins in a pin grid array arrangement or lands in a land grid array arrangement). The second-level interconnects 1720 may be used to couple the IC package 1700 to another component, such as a circuit board (e.g., a motherboard), an interposer, or another IC package, as known in the art and as discussed below with reference to FIG. 18.

In FIG. 17, the IC package 1700 is a flip chip package. The die 1706 may take the form of any of the examples of the die 1502 discussed herein (e.g., may include any of the examples of the IC device 1600).

Although the IC package 1700 illustrated in FIG. 17 is a flip chip package, other package architectures may be used. For example, the IC package 1700 may be a ball grid array (BGA) package, such as an embedded wafer-level ball grid array (eWLB) package. In another example, the IC package 1700 may be a wafer-level chip scale package (WLCSP) or a panel fanout (FO) package. Although a single die 1706 is illustrated in the IC package 1700 of FIG. 17, an IC package 1700 may include multiple dies 1706. An IC package 1700 may include additional passive components, such as surface-mount resistors, capacitors, and/or inductors disposed on the first face 1722 or the second face 1724 of the package substrate 1702. More generally, an IC package 1700 may include any other active and/or passive components known in the art.

FIG. 18 is a cross-sectional side view of an IC device assembly 1800 that may include the IC package 104 disclosed herein. In some examples, the IC device assembly corresponds to the IC package 104. The IC device assembly 1800 includes a number of components disposed on a circuit board 1802 (which may be, for example, a motherboard). The IC device assembly 1800 includes components disposed on a first face 1840 of the circuit board 1802 and an opposing second face 1842 of the circuit board 1802; generally, components may be disposed on one or both faces 1840 and 1842. Any of the IC packages discussed below with reference to the IC device assembly 1800 may take the form of the example IC package 104 of FIG. 1.

In some examples, the circuit board 1802 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1802. In other examples, the circuit board 1802 may be a non-PCB substrate.

The IC device assembly 1800. illustrated in FIG. 18. includes a package-on-interposer structure 1836 coupled to the first face 1840 of the circuit board 1802 by coupling components 1816. The coupling components 1816 may electrically and mechanically couple the package-on-interposer structure 1836 to the circuit board 1802, and may include solder balls (as shown in FIG. 18), male and female portions of a socket, an adhesive, an underfill material, and/or any other suitable electrical and/or mechanical coupling structure.

The package-on-interposer structure 1836 may include an IC package 1820 coupled to an interposer 1804 by coupling components 1818. The coupling components 1818 may take any suitable form for the application, such as the forms discussed above with reference to the coupling components 1816. Although a single IC package 1820 is shown in FIG. 18, multiple IC packages may be coupled to the interposer 1804; indeed, additional interposers may be coupled to the interposer 1804. The interposer 1804 may provide an intervening substrate used to bridge the circuit board 1802 and the IC package 1820. The IC package 1820 may be or include, for example, a die (the die 1502 of FIG. 15), an IC device (e.g., the IC device 1600 of FIG. 16), or any other suitable component. Generally, the interposer 1804 may spread a connection to a wider pitch or reroute a connection to a different connection. For example, the interposer 1804 may couple the IC package 1820 (e.g., a die) to a set of BGA conductive contacts of the coupling components 1816 for coupling to the circuit board 1802. In the example illustrated in FIG. 18, the IC package 1820 and the circuit board 1802 are attached to opposing sides of the interposer 1804; in other examples, the IC package 1820 and the circuit board 1802 may be attached to the same side of the interposer 1804. In some examples, three or more components may be interconnected by way of the interposer 1804.

In some examples, the interposer 1804 may be formed as a PCB, including multiple metal layers separated from one another by layers of dielectric material and interconnected by electrically conductive vias. In some examples, the interposer 1804 may be formed of an epoxy resin, a fiberglass-reinforced epoxy resin, an epoxy resin with inorganic fillers, a ceramic material, or a polymer material such as polyimide. In some examples, the interposer 1804 may be formed of alternate rigid or flexible materials that may include the same materials described above for use in a semiconductor substrate, such as silicon, germanium, and other group III-V and group IV materials. The interposer 1804 may include metal interconnects 1808 and vias 1810, including but not limited to through-silicon vias (TSVs) 1806. The interposer 1804 may further include embedded devices 1814, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1804. The package-on-interposer structure 1836 may take the form of any of the package-on-interposer structures known in the art.

The IC device assembly 1800 may include an IC package 1824 coupled to the first face 1840 of the circuit board 1802 by coupling components 1822. The coupling components 1822 may take the form of any of the examples discussed above with reference to the coupling components 1816, and the IC package 1824 may take the form of any of the examples discussed above with reference to the IC package 1820.

The IC device assembly 1800 illustrated in FIG. 18 includes a package-on-package structure 1834 coupled to the second face 1842 of the circuit board 1802 by coupling components 1828. The package-on-package structure 1834 may include a first IC package 1826 and a second IC package 1832 coupled together by coupling components 1830 such that the first IC package 1826 is disposed between the circuit board 1802 and the second IC package 1832. The coupling components 1828, 1830 may take the form of any of the examples of the coupling components 1816 discussed above, and the IC packages 1826, 1832 may take the form of any of the examples of the IC package 1820 discussed above. The package-on-package structure 1834 may be configured in accordance with any of the package-on-package structures known in the art.

FIG. 19 is a block diagram of an example electrical device 1900 that may include one or more of the example component stacks 100, 200, 600, 1200, 1300 and/or the associated mechanical locks 126, 202, 602, 1202, 1302. For example, any suitable ones of the components of the electrical device 1900 may include one or more of the device assemblies 1800, IC devices 1600, or dies 1502 disclosed herein, and may be arranged in the example component stacks 100, 200, 600, 1200, 1300. A number of components are illustrated in FIG. 19 as included in the electrical device 1900, but any one or more of these components may be omitted or duplicated, as suitable for the application. In some examples, some or all of the components included in the electrical device 1900 may be attached to one or more motherboards. In some examples, some or all of these components are fabricated onto a single system-on-a-chip (SoC) die.

Additionally, in various examples, the electrical device 1900 may not include one or more of the components illustrated in FIG. 19, but the electrical device 1900 may include interface circuitry for coupling to the one or more components. For example, the electrical device 1900 may not include a display 1906, but may include display interface circuitry (e.g., a connector and driver circuitry) to which a display 1906 may be coupled. In another set of examples, the electrical device 1900 may not include an audio input device 1918 (e.g., microphone) or an audio output device 1908 (e.g., a speaker, a headset, earbuds, etc.), but may include audio input or output device interface circuitry (e.g., connectors and supporting circuitry) to which an audio input device 1918 or audio output device 1908 may be coupled.

The electrical device 1900 may include programmable circuitry 1902 (e.g., one or more processing devices). The programmable circuitry 1902 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1900 may include a memory 1904, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 1904 may include memory that shares a die with the programmable circuitry 1902. This memory may be used as cache memory and may include embedded dynamic random access memory (eDRAM) or spin transfer torque magnetic random access memory (STT-MRAM).

In some examples, the electrical device 1900 may include a communication chip 1912 (e.g., one or more communication chips). For example, the communication chip 1912 may be configured for managing wireless communications for the transfer of data to and from the electrical device 1900. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples the associated devices might not.

The communication chip 1912 may implement any of a number of wireless standards or protocols, including but not limited to Institute of Electrical and Electronics Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1912 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1912 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1912 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. In other examples, the communication chip 1912 may operate in accordance with other wireless protocols. The electrical device 1900 may include an antenna 1922 to facilitate wireless communications and/or to receive other wireless communications (such as AM or FM radio transmissions).

In some examples, the communication chip 1912 may manage wired communications, such as electrical, optical, or any other suitable communication protocols (e.g., the Ethernet). As noted above, the communication chip 1912 may include multiple communication chips. For instance, a first communication chip 1912 may be dedicated to shorter-range wireless communications such as Wi-Fi or Bluetooth, and a second communication chip 1912 may be dedicated to longer-range wireless communications such as global positioning system (GPS), EDGE, GPRS, CDMA, WiMAX, LTE, EV-DO, or others. In some examples, a first communication chip 1912 may be dedicated to wireless communications, and a second communication chip 1912 may be dedicated to wired communications.

The electrical device 1900 may include battery/power circuitry 1914. The battery/power circuitry 1914 may include one or more energy storage devices (e.g., batteries or capacitors) and/or circuitry for coupling components of the electrical device 1900 to an energy source separate from the electrical device 1900 (e.g., AC line power).

The electrical device 1900 may include a display 1906 (or corresponding interface circuitry, as discussed above). The display 1906 may include any visual indicators, such as a heads-up display, a computer monitor, a projector, a touchscreen display, a liquid crystal display (LCD), a light-emitting diode display, or a flat panel display.

The electrical device 1900 may include an audio output device 1908 (or corresponding interface circuitry, as discussed above). The audio output device 1908 may include any device that generates an audible indicator, such as speakers, headsets, or earbuds.

The electrical device 1900 may include an audio input device 1918 (or corresponding interface circuitry, as discussed above). The audio input device 1918 may include any device that generates a signal representative of a sound, such as microphones, microphone arrays, or digital instruments (e.g., instruments having a musical instrument digital interface (MIDI) output).

The electrical device 1900 may include GPS circuitry 1916. The GPS circuitry 1916 may be in communication with a satellite-based system and may receive a location of the electrical device 1900, as known in the art.

The electrical device 1900 may include any other output device 1910 (or corresponding interface circuitry, as discussed above). Examples of the other output device 1910 may include an audio codec, a video codec, a printer, a wired or wireless transmitter for providing information to other devices, or an additional storage device.

The electrical device 1900 may include any other input device 1920 (or corresponding interface circuitry, as discussed above). Examples of the other input device 1920 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1900 may have any desired form factor, such as a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device. In some examples, the electrical device 1900 may be any other electronic device that processes data.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/- 10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time + 1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that provide multiple paths for loads to pass between a heatsink and a backplate in a heat dissipating component stack. Including multiple load paths in a component stack can distribute loads from shock event across the different paths rather than having all or substantially of the shock-induced forces passing through an IC package, which can overstress and/or damage the package and/or the electrical connections between the package and an underlying circuit board. More particularly, disclosed examples including one or more mechanical locks that operate independent of and are stiffer than the typical spring-loaded fasteners traditionally relied on to resist shock loads for improved restraint of a heatsink. The greater stiffness of the mechanical locks (relative to the traditional fasteners) enable usage of larger heatsinks that can provide better thermal cooling than is possible with existing (smaller) heatsinks. Further, the independent nature of the mechanical locks (e.g., the ability to tighten, loosen, and/or otherwise adjust the mechanical locks independent of the tightening, loosening, and/or adjusting of traditional spring-loaded fasteners) enables the spring-loaded fasteners to be precisely tuned for a given package to improve (e.g., optimize) the heat transfer between an IC package and a heatsink, again improving the thermal cooling capability of disclosed examples relative to known thermal management solutions. Disclosed systems, apparatus, articles of manufacture, and methods are accordingly directed to one or more improvement(s) in the operation of a machine such as a computer or other electronic and/or mechanical device.

Further examples and combinations thereof include the following:

Example 1 includes an apparatus comprising a heatsink, a spring-loaded fastener to urge the heatsink against an integrated circuit package, the integrated circuit package to be coupled to a circuit board, the integrated circuit package to be between the heatsink and the circuit board, and a lock to restrain movement of the heatsink relative to the circuit board independent of the spring-loaded fastener.

Example 2 includes any preceding clause(s) of example 1, wherein the lock is to restrain movement of the heatsink in six degrees of freedom.

Example 3 includes any preceding clause(s) of any one or more of examples 1-2, wherein the lock is to interface with a protrusion extending from at least one of a bolster plate or a backplate.

Example 4 includes any preceding clause(s) of example 3, wherein the protrusion is a post that is to extend through an opening in the heatsink.

Example 5 includes any preceding clause(s) of example 4, wherein the lock includes a collar to surround the post, and a nut to surround the collar, the nut to urge the collar against the post as the nut is rotated.

Example 6 includes any preceding clause(s) of example 5, wherein the nut includes tapered inner threads that engage with exterior threads on the collar.

Example 7 includes any preceding clause(s) of any one or more of examples 5-6, wherein the collar is to extend through the opening in the heatsink, the nut to engage with the collar on a side of the heatsink that faces away from the circuit board.

Example 8 includes any preceding clause(s) of any one or more of examples 5-7, wherein the collar is rigidly affixed to the heatsink.

Example 9 includes any preceding clause(s) of example 8, wherein the collar is rigidly affixed to the heatsink via a threaded connection.

Example 10 includes any preceding clause(s) of any one or more of examples 5-9, wherein the collar includes at least one cutout along at least a portion of an axial length of the collar.

Example 11 includes any preceding clause(s) of any one or more of examples 5-10, wherein the nut includes a bottom portion and a top portion, the bottom and top portions of the nut to captivate the collar therebetween.

Example 12 includes any preceding clause(s) of example 11, wherein the collar includes a first wall that varies in thickness about a circumference of the collar, and the bottom portion of the nut includes a second wall surrounding the first wall, the second wall having a shape that is complementary to the variation in the thickness of the first wall.

Example 13 includes any preceding clause(s) of example 12, wherein the thickness of the first wall increases from a first thickness at a first point on the collar to a second thickness at a second point on the collar, the first and second points circumferentially spaced apart along the first wall, the second thickness greater than the first thickness.

Example 14 includes any preceding clause(s) of example 13, wherein the first and second points define a first circumferential segment of the first wall that is less than an entire circumference of the first wall, the wall including a second segment that extends circumferentially along the first wall between a third point and a fourth point, the third point adjacent the second point, the thickness of the wall increasing from the first thickness at the third point to the second thickness at the fourth point.

Example 15 includes any preceding clause(s) of any one or more of examples 12-14, wherein the collar includes a slot extending through the wall along an axial length of the collar.

Example 16 includes any preceding clause(s) of example 15, wherein the slot extends an entire distance of the axial length of the collar.

Example 17 includes any preceding clause(s) of any one or more of examples 5-16, wherein the post includes at least one of threads, ridges, ribs, or a roughened surface to engage with the collar.

Example 18 includes any preceding clause(s) of any one or more of examples 4-17, wherein the post is a threaded post, and the lock includes a locking nut to be threaded on to the post, the heatsink to be between the locking nut and the circuit board.

Example 19 includes any preceding clause(s) of any one or more of examples 3-18, wherein the protrusion is to extend adjacent to a side edge of the heatsink.

Example 20 includes any preceding clause(s) of example 19, wherein the protrusion is a tab that includes an elongated slot extending transverse to the circuit board, the lock including a screw to be threaded into a hole in the side edge of the heatsink, the screw to pass through the elongated slot.

Example 21 includes any preceding clause(s) of example 20, wherein the tab is located in a notch in the side edge of the heatsink.

Example 22 includes an apparatus comprising an integrated circuit package on a first side of a circuit board, a backplate on a second side of the circuit board opposite the first side, a heatsink thermally coupled to the integrated circuit package, the integrated circuit package between the heatsink and the circuit board, spring-loaded fasteners to urge the backplate and the heatsink towards each other to place the integrated circuit package in compression, and a lock to secure the heatsink in fixed spatial relationship to the integrated circuit package, the lock distinct from the spring-loaded fasteners.

Example 23 includes any preceding clause(s) of example 22, wherein the lock includes a collar that is to clamp onto a post, the post rigidly coupled to at least one of the backplate or a bolster plate.

Example 24 includes any preceding clause(s) of example 23, including a nut to selectively tighten or loosen the collar around the post independent of the spring-loaded fasteners, the post to be freely moveable through the collar when the nut loosens the collar.

Example 25 includes any preceding clause(s) of any one or more of examples 23-24, wherein the collar includes a slot extending along at least part of an axial length of the collar.

Example 26 includes any preceding clause(s) of any one or more of examples 22-25, wherein the lock includes a flange that extends from the backplate adjacent a side edge of the heatsink, and a screw that threads into a hole in the side edge of the heatsink through a slot in the flange.

Example 27 includes any preceding clause(s) of any one or more of examples package-26, means for cooling the integrated circuit package, means for urging the means for cooling towards the integrated circuit package, and means for locking the means for cooling in place relative to the integrated circuit package, the means for locking different from the means for urging.

Example 28 includes any preceding clause(s) of example 27, wherein the means for locking includes means for spanning a distance between a bolster plate and the means for cooling, the bolster plate surrounding the integrated circuit package on a circuit board.

Example 29 includes any preceding clause(s) of example 28, wherein the means for locking includes means for gripping the means for spanning.

Example 30 includes any preceding clause(s) of example 29, wherein the means for locking includes means for tightening the means for gripping.

Example 31 includes any preceding clause(s) of any one or more of examples 28-30, wherein the means for locking includes means for fastening the means for spanning in fixed relationship to the means for cooling.

Example 32 includes a method comprising tightening spring-loaded fasteners between a heatsink and at least one of a bolster plate or a backplate, the spring-loaded fasteners to urge the heatsink towards an integrated circuit package between the heatsink and the backplate, and tightening a mechanical lock to secure the heatsink in fixed spatial relationship to the integrated circuit package.

Example 33 includes any preceding clause(s) of example 32, wherein the tightening of the mechanical lock is performed after the tightening of the spring-loaded fasteners.

Example 34 includes any preceding clause(s) of any one or more of examples 32-33, including connecting the integrated circuit package to a circuit board using solder.

Example 35 includes any preceding clause(s) of any one or more of examples 32-34, including connecting the integrated circuit package to a circuit board via a socket.

Example 36 includes any preceding clause(s) of any one or more of examples 32-35, wherein the tightening of the mechanical lock includes rotating a nut relative to a post.

Example 37 includes any preceding clause(s) of example 36, wherein rotation of the nut is to tighten a collar around the post.

Example 38 includes any preceding clause(s) of any one or more of examples 32-37, wherein the tightening of the mechanical lock includes threading a screw into a hole in a side edge of the heatsink, the screw to pass through a slot in a flange protruding from the at least one of the bolster plate or the backplate.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. An apparatus comprising:
a heatsink;
a spring-loaded fastener to urge the heatsink against an integrated circuit package, the integrated circuit package to be coupled to a circuit board, the integrated circuit package to be between the heatsink and the circuit board; and
a lock to restrain movement of the heatsink relative to the circuit board independent of the spring-loaded fastener.

2. The apparatus of claim 1, wherein the lock is to interface with a protrusion extending from at least one of a bolster plate or a backplate.

3. The apparatus of claim 2, wherein the protrusion is a post that is to extend through an opening in the heatsink.

4. The apparatus of claim 3, wherein the lock includes:
a collar to surround the post; and
a nut to surround the collar, the nut to urge the collar against the post as the nut is rotated.

5. The apparatus of claim 4, wherein the nut includes tapered inner threads that engage with exterior threads on the collar.

6. The apparatus of claim 4, wherein the collar includes at least one cutout along at least a portion of an axial length of the collar.

7. The apparatus of claim 4, wherein the nut includes a bottom portion and a top portion, the bottom and top portions of the nut to captivate the collar therebetween.

8. The apparatus of claim 7, wherein the collar includes a first wall that varies in thickness about a circumference of the collar, and the bottom portion of the nut includes a second wall surrounding the first wall, the second wall having a shape that is complementary to the variation in the thickness of the first wall.

9. The apparatus of claim 8, wherein the thickness of the first wall increases from a first thickness at a first point on the collar to a second thickness at a second point on the collar, the first and second points circumferentially spaced apart along the first wall, the second thickness greater than the first thickness.

10. The apparatus of claim 9, wherein the first and second points define a first circumferential segment of the first wall that is less than an entire circumference of the first wall, the wall including a second segment that extends circumferentially along the first wall between a third point and a fourth point, the third point adjacent the second point, the thickness of the wall increasing from the first thickness at the third point to the second thickness at the fourth point.

11. The apparatus of claim 8, wherein the collar includes a slot extending through the wall along an axial length of the collar.

12. The apparatus of claim 3, wherein the post is a threaded post, and the lock includes a locking nut to be threaded on to the post, the heatsink to be between the locking nut and the circuit board.

13. The apparatus of claim 2, wherein the protrusion is to extend adjacent to a side edge of the heatsink.

14. The apparatus of claim 13, wherein the protrusion is a tab that includes an elongated slot extending transverse to the circuit board, the lock including a screw to be threaded into a hole in the side edge of the heatsink, the screw to pass through the elongated slot.

15. An apparatus comprising:
an integrated circuit package on a first side of a circuit board;
a backplate on a second side of the circuit board opposite the first side;
a heatsink thermally coupled to the integrated circuit package, the integrated circuit package between the heatsink and the circuit board;
spring-loaded fasteners to urge the backplate and the heatsink towards each other to place the integrated circuit package in compression; and
a lock to secure the heatsink in fixed spatial relationship to the integrated circuit package, the lock distinct from the spring-loaded fasteners.

16. The apparatus of claim 15, wherein the lock includes a collar that is to clamp onto a post, the post rigidly coupled to at least one of the backplate or a bolster plate.

17. The apparatus of claim 16, including a nut to selectively tighten or loosen the collar around the post independent of the spring-loaded fasteners, the post to be freely moveable through the collar when the nut loosens the collar.

18. An apparatus comprising:
an integrated circuit package;
means for cooling the integrated circuit package;
means for urging the means for cooling towards the integrated circuit package; and
means for locking the means for cooling in place relative to the integrated circuit package, the means for locking different from the means for urging.

19. The apparatus of claim 18, wherein the means for locking includes means for spanning a distance between a bolster plate and the means for cooling, the bolster plate surrounding the integrated circuit package on a circuit board.

20. The apparatus of claim 19, wherein the means for locking includes means for gripping the means for spanning.
